(19) United States
(12) Patent Application Publication
(10) Pub. No.: US 2025/0143113 A1
(43) Pub. Date: May 1, 2025

(54) DISPLAY PANEL AND DISPLAY DEVICE

(71) Applicants: Chengdu BOE Optoelectronics Technology Co., Ltd., Sichuan (CN); BOE Technology Group Co. Ltd., Beijing (CN)

(72) Inventors: Lingtong LI, Beijing (CN); Xiaoqing SHU, Beijing (CN); Huijuan YANG, Beijing (CN); Maoying LIAO, Beijing (CN); Liheng WEI, Beijing (CN); Nanhao CHEN, Beijing (CN); Yixuan LONG, Beijing (CN)

(21) Appl. No.: 18/693,548

(22) PCT Filed: May 31, 2022
(86) PCT No.: PCT/CN2022/096130

§ 371 Date: Mar. 20, 2024

(51) Int. Cl. H10K 59/131; G09G 3/3233; H10K 59/121

(52) U.S. Cl. CPC H10K 59/131; H10K 59/1213; G09G 3/3233; G09G 2300/0426; G09G 2300/0819; G09G 2300/0842; G09G 2300/0861; G09G 2310/0286; H10K 59/1216

(57) ABSTRACT

A display panel including a pixel driving circuit having driving transistor and fourth transistor is provided. The fourth transistor includes a first electrode connected to a data line and a second electrode connected to a first electrode of the driving transistor. The display panel includes: a first conductive layer provided on a base substrate and including a gate line and first conductive part, a portion of the gate line forming a gate electrode of the fourth transistor, the first conductive part forming a gate electrode of the driving transistor; a second conductive part connected to the gate line; a third conductive part provided in a different layer from the second conductive part, an orthographic projection of the third conductive part on the base substrate being partially overlapped with that of the second conductive part; a first bridging part connected to the third conductive part and the first conductive part.

### CROSS-REFERENCE TO RELATED APPLICATIONS

The present application is a U.S. National Stage of International Application No. PCT/CN2022/096130 filed on May 31, 2022, the entire contents of which are incorporated herein by reference.

### TECHNICAL FIELD

The present disclosure relates to the field of display technology, and specifically, to a display panel and a display device.

### BACKGROUND

In the related art, a display panel needs a relatively large data signal voltage to display a black frame, which results in high power consumption of the display panel.

It is to be noted that the information disclosed in the above background section is only used to enhance the understanding of the background of the present disclosure, and thus may include information that does not constitute the prior art known to those skilled in the art.

### SUMMARY

One aspect of the present disclosure provides a display panel including a pixel driving circuit, wherein the pixel driving circuit includes a driving transistor and a fourth transistor, the fourth transistor includes a first electrode connected to a data line and a second electrode connected to a first electrode of the driving transistor, and the display panel further includes: a base substrate; a first conductive layer provided on a side of the base substrate and including a first gate line and a first conductive part, an orthographic projection, on the base substrate, of the first gate line extending in a first direction, a portion of the first gate line being configured to form a gate electrode of the fourth transistor, and the first conductive part being configured to form a gate electrode of the driving transistor; a second conductive part connected to the first gate line; a third conductive part provided in a different conductive layer from the second conductive layer, an orthographic projection, on the base substrate, of the third conductive part being at least partially overlapped with an orthographic projection, on the base substrate, of the second conductive part; and a fourth conductive layer provided on a side, away from the base substrate, of the first conductive layer and including a first bridging part, the first bridging part being connected to the third conductive part and the first conductive part through via-holes respectively.

In an embodiment of the present disclosure, the pixel driving circuit further includes an eighth transistor, a first transistor, and a second transistor, the eighth transistor includes a first electrode connected to the gate electrode of the driving transistor and a second electrode connected to a second electrode of the first transistor, the first transistor includes a first electrode connected to a first initial signal line, and the second transistor includes a first electrode connected to the second electrode of the eighth transistor and a second electrode connected to the second electrode of the driving transistor.

In an embodiment of the present disclosure, a conductive layer in which the second conductive part is located is provided in the first conductive layer or between the first conductive layer and the fourth conductive layer, and a conductive layer in which the third conductive part is located is provided between the conductive layer in which the second conductive part is located and the fourth conductive layer.

In an embodiment of the present disclosure, the pixel driving circuit further includes a capacitor, the capacitor includes a first electrode connected to the gate electrode of the driving transistor and a second electrode connected to a power line, and the first conductive part is further configured to form the first electrode of the capacitor, the display panel further includes a second conductive layer, and the second conductive layer is provided between the first conductive layer and the fourth conductive layer, and includes: a fourth conductive part having an orthographic projection on the base substrate at least partially overlapped with an orthographic projection, on the base substrate, of the first conductive part, the fourth conductive part being configured to form the second electrode of the capacitor, and wherein the third conductive part is provided in the second conductive layer.

In an embodiment of the present disclosure, the display panel further includes: a second active layer provided between the first conductive layer and the fourth conductive layer and including an eighth active part, the eighth active part being configured to form a channel region of the eighth transistor, and wherein the third conductive part is provided in the second active layer.

In an embodiment of the present disclosure, the orthographic projection, on the base substrate, of the second conductive part is located at a side, away from an orthographic projection of the first conductive part on the base substrate, of the orthographic projection, on the base substrate, of the first gate line, and the orthographic projection, on the base substrate, of the third conductive part is located at a side, away from the orthographic projection of the first conductive part on the base substrate, of the orthographic projection, on the base substrate, of the first gate line.

In an embodiment of the present disclosure, the pixel driving circuit further includes a second transistor, the second transistor includes a first electrode connected to the gate electrode of the driving transistor and a second electrode connected to the second electrode of the driving transistor, and a portion of the first gate line is configured to form a gate electrode of the second transistor, the display panel further includes: a first active layer provided between the base substrate and the first conductive layer and including a second active part and a fourth active part, the orthographic projection, on the base substrate, of the first gate line covering an orthographic projection, on the base substrate, of the second active part and an orthographic projection, on the base substrate, of the fourth active part, the second active part being configured to form a channel region of the second transistor, and the fourth active part being configured to forming a channel region of the fourth transistor, and wherein in the first direction, the orthographic projection, on the base substrate, of the second conductive part is located between the orthographic projection, on the base substrate, of the second active part and the orthographic projection, on the base substrate, of the fourth active part.

In an embodiment of the present disclosure, in the first direction, the orthographic projection, on the base substrate, of the third conductive part is located between the orthographic projection, on the base substrate, of the second active part and the orthographic projection, on the base substrate, of the fourth active part, and a distance in the first direction between the orthographic projection, on the base substrate, of the third conductive part and the orthographic projection, on the base substrate, of the fourth active part is greater than a distance in the first direction between the orthographic projection, on the base substrate, of the third conductive part and the orthographic projection, on the base substrate, of the second active part.

In an embodiment of the present disclosure, the third conductive part includes a first edge and a second edge provided opposite to each other in the first direction, and a third edge and a fourth edge provided opposite to each other in a second direction intersecting the first direction, the second conductive part includes a fifth edge and a sixth edge provided opposite to each other in the first direction, in the first direction, an orthographic projection, on the base substrate, of the fifth edge is located between an orthographic projection, on the base substrate, of the first edge and an orthographic projection, on the base substrate, of the second edge, and an orthographic projection, on the base substrate, of the sixth edge is located between the orthographic projection, on the base substrate, of the first edge and the orthographic projection, on the base substrate, of the second edge, and both of an orthographic projection, on the base substrate, of the third edge, and an orthographic projection, on the base substrate, of the fourth edge intersect with the orthographic projection, on the base substrate, of the second conductive part.

In an embodiment of the present disclosure, the display panel further includes: a second active layer provided between the first conductive layer and the fourth conductive layer and including an eighth active part, the eighth active part being configured to form a channel region of the eighth transistor; and a third conductive layer provided between the second active layer and the fourth conductive layer and including a second gate line, an orthographic projection, on the base substrate, of the second gate line extending in the first direction and covering an orthographic projection, on the base substrate, of the eighth active part, and a portion of the second gate line being configured to form a top gate electrode of the eighth transistor, wherein the orthographic projection, on the base substrate, of the second gate line is located between an orthographic projection, on the base substrate, of the first conductive part and the orthographic projection, on the base substrate, of the first gate line.

In an embodiment of the present disclosure, the display panel further includes: a second conductive layer provided between the first conductive layer and the second active layer and including a third gate line, an orthographic projection, on the base substrate, of the third gate line extending in the first direction and covering the orthographic projection, on the base substrate, of the eighth active part, and a portion of the third gate line being configured to form a bottom gate electrode of the eighth transistor, the third conductive layer further includes a fifth conductive part, the fifth conductive part is connected to the second gate line, and has an orthographic projection on the base substrate located at a side, facing towards the orthographic projection of the first gate line on the base substrate, of the orthographic projection, on the base substrate, of the second gate line, the fifth conductive part includes a seventh edge away from the second gate line and an eighth edge connected to the seventh edge, and the seventh edge has an orthographic projection on the base substrate extending in the first direction and intersecting with an orthographic projection, on the base substrate, of the eighth edge, the second gate line includes a ninth edge and a tenth edge provided opposite to each other in a second direction intersecting with the first direction, an orthographic projection, on the base substrate, of the ninth edge and an orthographic projection, on the base substrate, of the tenth edge both extend in the first direction, the orthographic projection, on the base substrate, of the ninth edge is located at a side, facing towards the orthographic projection of the first gate line on the base substrate, of the orthographic projection, on the base substrate, of the tenth edge, the ninth edge is connected to the eighth edge, an angle between the orthographic projection, on the base substrate, of the eighth edge and the orthographic projection, on the base substrate, of the ninth edge is less than 180°, the third gate line includes an eleventh edge and a twelfth edge provided opposite to each other in the second direction, an orthographic projection, on the base substrate, of the eleventh edge and an orthographic projection, on the base substrate, of the twelfth edge both extend in the first direction, and the orthographic projection, on the base substrate, of the eleventh edge is located at a side, facing towards the orthographic projection of the first gate line on the base substrate, of the orthographic projection, on the base substrate, of the twelfth edge, an orthographic projection, on the base substrate, of the first bridging part is overlapped with the orthographic projection, on the base substrate, of the seventh edge, the orthographic projection, on the base substrate, of the tenth edge, the orthographic projection, on the base substrate, of the eleventh edge, and the orthographic projection, on the base substrate, of the twelfth edge, an orthographic projection, on the base substrate, of a portion of the first bridging part is overlapped with both of the orthographic projection, on the base substrate, of the second gate line and the orthographic projection, on the base substrate, of the third gate line.

In an embodiment of the present disclosure, a distance in the second direction between the orthographic projection, on the base substrate, of the seventh edge and the orthographic projection, on the base substrate, of the eleventh edge is greater than a distance in the second direction between the orthographic projection, on the base substrate, of the ninth edge and the orthographic projection, on the base substrate, of the eleventh edge.

In an embodiment of the present disclosure, the orthographic projection, on the base substrate, of the seventh edge is located on the orthographic projection, on the base substrate, of the first gate line.

In an embodiment of the present disclosure, the display panel further includes a light emitting unit, the pixel driving circuit further includes a fifth transistor, a sixth transistor and a seventh transistor, the fifth transistor includes a first electrode connected to the power line and a second electrode connected to the first electrode of the driving transistor, the sixth transistor includes a first electrode connected to the second electrode of the driving transistor and a second electrode connected to a first electrode of the light emitting unit, and the seventh transistor includes a first electrode connected to a second initial signal line and a second electrode connected to the first electrode of the light emitting unit, the display panel further includes: a first active layer provided between the base substrate and the first conductive layer, the first active layer including a first active part, a fifth active part, a sixth active part and a seventh active part, the first active part being configured to form a channel region of the first transistor, the fifth active part being configured to form a channel region of the fifth transistor, the sixth active part being configured to form a channel region of the sixth transistor, and the seventh active part being configured to a channel region of the seventh transistor, the first conductive layer further includes: an enabling signal line, an orthographic projection, on the base substrate, of the enabling signal line extending in the first direction and covering an orthographic projection, on the base substrate, of the fifth active part and an orthographic projection, on the base substrate, of the sixth active part, a portion of the enabling signal line being configured to form a gate electrode of the fifth transistor, and another portion of the enabling signal line being configured to form a gate electrode of the sixth transistor; and a first reset signal line, an orthographic projection, on the base substrate, of the first reset signal line extending in the first direction and covering an orthographic projection, on the base substrate, of the first active part, and a portion of the first reset signal line being configured to form the gate electrode of the first transistor; and a second reset signal line, an orthographic projection, on the base substrate, of the second reset signal line extending in the first direction and covering an orthographic projection, on the base substrate, of the seventh active part, and a portion of the second reset signal line being configured to form a gate electrode of the seventh transistor, wherein the orthographic projection, on the base substrate, of the enable signal line is located at a side, away from the orthographic projection of the first gate line on the base substrate, of the orthographic projection, on the base substrate, of the first conductive part, the orthographic projection, on the base substrate, of the second reset signal line is located at a side, away from the orthographic projection of the first conductive part on the base substrate, of the orthographic projection, on the base substrate, of the enable signal line, and the orthographic projection, on the base substrate, of the first reset signal line is located at a side, away from the orthographic projection of the first conductive part on the base substrate, of the orthographic projection, on the base substrate, of the first gate line.

In an embodiment of the present disclosure, the first direction is a row direction, and the second reset signal line in the pixel driving circuit in a previous row adjacent to a current row is multiplexed as the first reset signal line in the pixel driving circuit in the current row.

In an embodiment of the present disclosure, the first direction is a row direction, and the third conductive layer further includes the first initial signal line, an orthographic projection, on the base substrate, of the first initial signal line extends in the first direction and is located at a side, away from the orthographic projection of the first conductive part on the base substrate, of an orthographic projection, on the base substrate, of the first reset signal line, the orthographic projection, on the base substrate, of the first initial signal line in the pixel driving circuit in a next row adjacent to a current row is located between the orthographic projection, on the base substrate, of the second reset signal line in the pixel driving circuit in the current row and the orthographic projection, on the base substrate, of the first conductive part in the pixel driving circuit in the current row, and the orthographic projection, on the base substrate, of the first initial signal line in the pixel driving circuit in the next row is at least partially overlapped with the orthographic projection, on the base substrate, of the enable signal line in the pixel driving circuit in the current row.

In an embodiment of the present disclosure, the first direction is a row direction, and the fourth conductive layer further includes the second initial signal line, an orthographic projection, on the base substrate, of the second initial signal line extends in the first direction and is located at a side, away from the orthographic projection of the first conductive part on the base substrate, of the orthographic projection, on the base substrate, of the second reset signal line, the orthographic projection, on the base substrate, of the second initial signal line in the pixel driving circuit in a previous row adjacent to a current row is located between the orthographic projection, on the base substrate, of the first reset signal line in the pixel driving circuit in the current row and the orthographic projection, on the base substrate, of the first gate line in the pixel driving circuit in the current row.

In an embodiment of the present disclosure, the display panel further includes: a second active layer provided between the first conductive layer and the fourth conductive layer and including an eighth active part, the eighth active part being configured to form a channel region of the eighth transistor; and a fifth conductive layer provided on a side, away from the base substrate, of the fourth conductive layer and including a power line, the power line including a first extension part, a second extension part and a third extension part, and the second extension part being connected between the first extension part and the third extension part, wherein a dimension in the first direction of an orthographic projection, on the base substrate, of the second extension part is greater than a dimension in the first direction of an orthographic projection, on the base substrate, of the first extension part and a dimension in the first direction of an orthographic projection, on the base substrate, of the third extension part, and the orthographic projection, on the base substrate, of the second extension part covers the orthographic projection, on the base substrate, of the eighth active part, and an orthographic projection, on the base substrate, of the first bridging part.

In an embodiment of the present disclosure, the pixel driving circuit further includes a capacitor, the capacitor includes a first electrode connected to the gate electrode of the driving transistor and a second electrode connected to a power line, the power line includes a first extension part, a second extension part and a third extension part, and the second extension part is connected between the first extension part and the third extension part, the first direction is a row direction, the display panel includes a plurality of repeating units arranged in the row direction and a column direction, each of the repeating units includes two pixel driving circuits, the two pixel driving circuits include a first pixel driving circuit and a second pixel driving circuit arranged in the row direction, and the first pixel driving circuit and the second pixel driving circuit are arranged in a mirrored and symmetrical manner, the pixel driving circuits in each column are provided to correspond to one power line, and in a same repeating unit, the second extension parts of two power lines are connected, the display panel further includes a second conductive layer, the second conductive layer is provided between the first conductive layer and the fourth conductive layer, and the second conductive layer includes: a fourth conductive part, an orthographic projection, on the base substrate, of the fourth conductive part being at least partially overlapped with an orthographic projection, on the base substrate, of the first conductive part, and the fourth conductive part being configured to form the second electrode of the capacitor, in the repeating units adjacent in the row direction, adjacent fourth conductive parts are connected.

In an embodiment of the present disclosure, the second conductive layer further includes a first connection part, and in the repeating units adjacent in the row direction, the adjacent fourth conductive parts are connected by the first connection part, the pixel driving circuit further includes a fifth transistor, and the fifth transistor includes a first electrode connected to the power line and a second electrode connected to the first electrode of the driving transistor, the display panel further includes a first active layer provided between the base substrate and the first conductive layer, and the first active layer includes: a third active part configured to form a channel region of the driving transistor; a fifth active part configured to form a channel region of the fifth transistor; and a ninth active part connected to a side, away from the third active part, of the fifth active part, and connected between two fifth active parts in the repeating units adjacent in the row direction, and the fourth conductive layer further includes: a second bridging part respectively connected to the ninth active part and the first connection part through via-holes, and connected to the power line through a via-hole. In an embodiment of the present disclosure, the first transistor, the second transistor, the driving transistor, the fourth transistor, the fifth transistor, the sixth transistor, and the seventh transistor are P-type transistors, and the eighth transistor is an N-type transistor.

One aspect of the present disclosure provides a display device including the display panel described above.

It should be understood that the above general description and the following detailed descriptions are and explanatory only and do not limit the embodiments of the present disclosure.

### BRIEF DESCRIPTION OF THE DRAWINGS

The accompanying drawings herein are incorporated into and form a part of the specification, illustrate embodiments consistent with the present disclosure, and are used in conjunction with the specification to explain the principle of the present disclosure. Obviously, the accompanying drawings in the following description are only some of the embodiments of the present disclosure, and those skilled in the art may obtain other accompanying drawings from these drawings without creative work.

FIG. 1 is a schematic diagram of a circuit structure of a pixel driving circuit in a display panel according to an embodiment of the present disclosure;

FIG. 2 is a functional block diagram of a display panel according to an embodiment of the present disclosure;

FIG. 3 is a timing diagram of signals on output terminals of some shift register units in FIG. 2;

FIG. 4 is a structural layout of a display panel according to an embodiment of the present disclosure;

FIG. 5 is a structural layout of a light-shielding layer in FIG. 4;

FIG. 6 is a structural layout of a first active layer in FIG. 4;

FIG. 7 is a structural layout of a first conductive layer in FIG. 4;

FIG. 8 is a structural layout of a second conductive layer in FIG. 4;

FIG. 9 is a structural layout of a second active layer in FIG. 4;

FIG. 10 is a structural layout of a third conductive layer in FIG. 4;

FIG. 11 is a structural layout of a fourth conductive layer in FIG. 4;

FIG. 12 is a structural layout of a fifth conductive layer in FIG. 4;

FIG. 13 is a structural layout of an electrode layer in FIG. 4;

FIG. 14 is a structural layout of the light-shielding layer and the first active layer in FIG. 4;

FIG. 15 is a structural layout of the light-shielding layer, the first active layer, and the first conductive layer in FIG. 4;

FIG. 16 is a structural layout of the light-shielding layer, the first active layer, the first conductive layer, and the second conductive layer in FIG. 4;

FIG. 17 is a structural layout of the light-shielding layer, the first active layer, the first conductive layer, the second conductive layer, and the second active layer in FIG. 4;

FIG. 18 is a structural layout of the light-shielding layer, the first active layer, the first conductive layer, the second conductive layer, the second active layer, and the third conductive layer in FIG. 4;

FIG. 19 is a structural layout of the light-shielding layer, the first active layer, the first conductive layer, the second conductive layer, the second active layer, the third conductive layer, and the fourth conductive layer in FIG. 4;

FIG. 20 is a structural layout of the light-shielding layer, the first active layer, the first conductive layer, the second conductive layer, the second active layer, the third conductive layer, the fourth conductive layer, and the fifth conductive layer in FIG. 4; and

FIG. 21 is a partial sectional view of the display panel shown in FIG. 4 taken along a dashed line AA.

### DETAILED DESCRIPTION

Example embodiments will now be described more fully with reference to the accompanying drawings. However, the example embodiments may be implemented in a variety of forms and should not be construed as being limited to the examples set forth herein; rather, these embodiments are provided so that the present disclosure is comprehensive and complete and the concept of the example embodiments is conveyed to those skilled in the art in a comprehensive manner. The same reference numerals in the drawings denote the same or similar structures, and thus their detailed descriptions will be omitted.

The terms “a”, “an”, “said” are used to indicate the presence of one or more elements/components/etc.; the terms “including” and “having” are used to indicate open-ended inclusion and mean that there may be additional elements/components/etc. in addition to those listed.

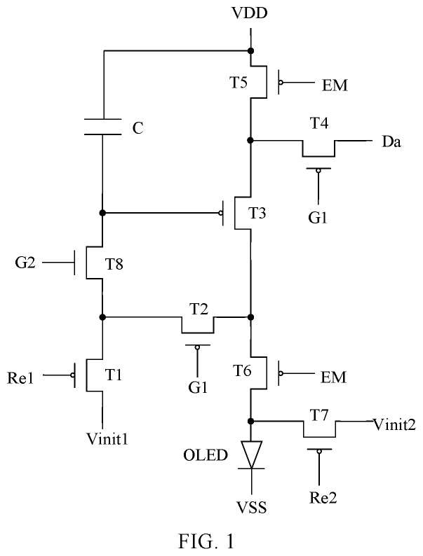

As shown in FIG. 1, FIG. 1 is a schematic diagram of a circuit structure of a pixel driving circuit in a display panel according to an embodiment of the present disclosure. The pixel driving circuit may include a first transistor T1, a second transistor T2, a driving transistor T3, a fourth transistor T4, a fifth transistor T5, a sixth transistor T6, a seventh transistor T7, an eighth transistor T8, and a capacitor C. A first electrode of the eighth transistor T8 is connected to a gate electrode of the driving transistor T3, and a gate electrode of the eighth transistor T8 is connected to a second gate driving signal terminal G2. A first electrode of the first transistor T1 is connected to a first initial signal terminal Vinit1, a second electrode of the first transistor T1 is connected to a second electrode of the eighth transistor T8, and a gate electrode of the first transistor T1 is connected to a first reset signal terminal Re1. A first electrode of the second transistor T2 is connected to the second electrode of the eighth transistor T8, a second electrode of the second transistor T2 is connected to a second electrode of the driving transistor T3, and a gate electrode of the second transistor T2 is connected to a first gate driving signal terminal G1. A first electrode of the fourth transistor T4 is connected to a data signal terminal Da, a second electrode of the fourth transistor T4 is connected to a first electrode of the driving transistor T3, and a gate electrode of the fourth transistor T4 is connected to the first gate driving signal terminal G1. A first electrode of the fifth transistor T5 is connected to a first power supply terminal VDD, a second electrode of the fifth transistor T5 is connected to the first electrode of the driving transistor T3, and a gate electrode of the fifth transistor T5 is connected to an enable signal terminal EM. A first electrode of the sixth transistor T6 is connected to the second electrode of the driving transistor T3, and a gate electrode of the sixth transistor T6 is connected to the enable signal terminal EM. A first electrode of the seventh transistor T7 is connected to a second initial signal terminal Vinit2, a second electrode of the seventh transistor T7 is connected to a second electrode of the sixth transistor T6, and a gate electrode of the seventh transistor T7 is connected to a second reset signal terminal Re2. A first electrode of the capacitor is connected to the gate electrode of the driving transistor T3, and a second electrode of the capacitor is connected to the first power supply terminal VDD. The pixel driving circuit may be used to drive a light-emitting unit OLED to emit light, a first electrode of the light-emitting unit OLED is connected to the second electrode of the sixth transistor T6, and a second electrode of the light-emitting unit OLED is connected to a second power supply terminal VSS. The first transistor T1, the second transistor T2, the driving transistor T3, the fourth transistor T4, the fifth transistor T5, the sixth transistor T6, and the seventh transistor T7 may all be P-type transistors, and the eighth transistor T8 may be an N-type transistor.

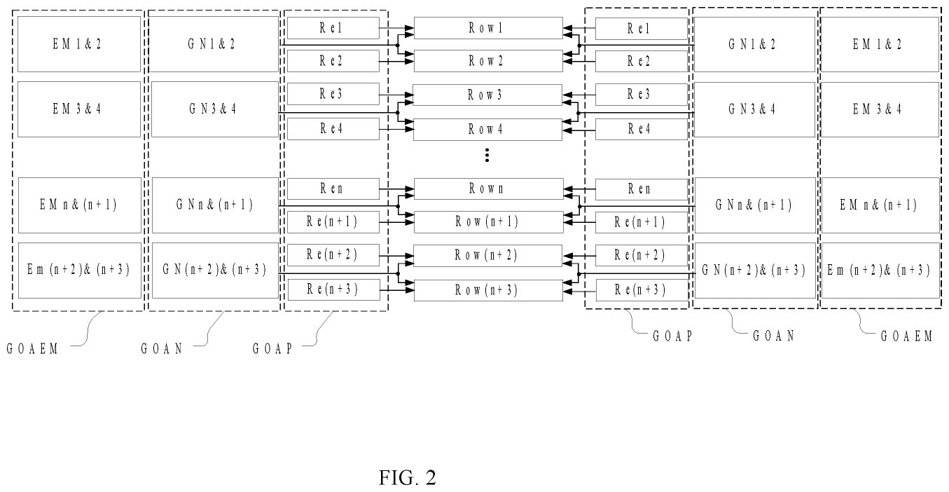

As shown in FIG. 2, FIG. 2 is a functional block diagram of a display panel according to an embodiment of the present disclosure. The display panel includes a plurality of pixel driving circuits arranged in an array along a row direction and a column direction. ROW1 denotes a first row of pixel driving circuits, ROW2 denotes a second row of pixel driving circuits, and so on, and ROWn denotes an n^{th} row of pixel driving circuits, where n is a positive integer greater than 4. The display panel may further include a first gate driving circuit GOAP, a second gate driving circuit GOAN, and a third gate driving circuit GOAEM. The first gate driving circuit GOAP may include a plurality of cascade-connected first shift register units Re1 . . . Re(n+16), the first shift register units Re1 . . . Re(n+16) sequentially output shift signals, an output terminal of the first shift register unit Re1 of the first stage is connected to the first reset signal terminal of the first row of pixel driving circuits Row1, the first shift register unit Re2 of the second stage is connected to the first reset signal terminal of the second row of pixel driving circuits Row2, and so on, the output terminal of the first shift register unit Ren of the n^{th} stage is connected to the first reset signal terminal of the n^{th} row of pixel driving circuits. In addition, the output terminal of the first shift register unit Re(n+10) of the (n+10)^{th} stage may also be connected to the first gate driving signal terminal in the (n−4)^{th} row of pixel driving circuits. The second gate driving circuit GOAN includes a plurality of cascade-connected second shift register units GN1&2, GN3&4 . . . GNn&(n+1), GN(n+2)&(n+3). The second shift register unit GN1&2 of the first stage is connected to the second gate driving signal terminals G2 in the first row of pixel driving circuits Row1 and the second row of pixel driving circuits Row2, and so on, the second shift register unit GNn&(n+1) of the (n+1)/2^{th} stage is connected to the second gate driving signal terminals in the n^{th} row of pixel driving circuits Rown and the (n+1)^{th} row of pixel driving circuits Row (n+1). The third gate driving circuit GOAEM may include a plurality of cascade-connected third shift register units EM1&2, EM3&4, EMn&(n+1), and Em(n+2)&(n+3) sequentially. The third shift register unit EM1&2 of the first stage is connected to the enable signal terminals EM in the first row of pixel driving circuits Row1 and the second row of pixel driving circuits Row2, and so on, the third shift register unit EMn&(n+1) of the (n+1)/2^{th} stage is connected to the enable signal terminals in the n^{th} row of pixel driving circuits Rown and the (n+1)^{th} row of pixel driving circuits Row (n+1). In addition, in the display panel, the first reset signal terminal in a current row of pixel driving circuits and the second reset signal terminal in a previous row of pixel driving circuits adjacent to the current row may be connected to an output terminal of the first shift register unit of the same stage. The display panel may be provided with two groups of first gate driving circuits GOAP, two groups of second gate driving circuits GOAN, and two groups of third gate driving circuits GOAEM. The two groups of first gate driving circuits GOAP are respectively provided at both sides of the display panel in the row direction to drive the corresponding gate lines respectively. The two groups of second gate driving circuits GOAN are respectively provided at both sides of the display panel in the row direction to drive the corresponding gate lines respectively. The two groups of third gate driving circuits GOAEM are respectively provided at both sides of the display panel in the row direction to drive the corresponding gate lines respectively.

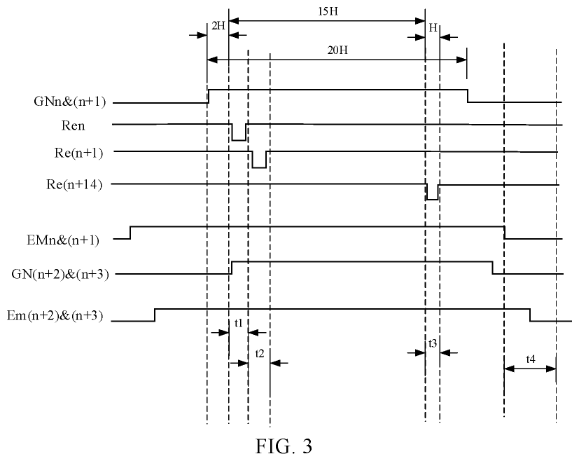

As shown in FIG. 3, FIG. 3 is a timing diagram of signals on output terminals of some shift register units in FIG. 2. Ren denotes a timing diagram of the signal on the output terminal of the first shift register unit Ren of the n^{th} stage, Re(n+1) denotes a timing diagram of the signal on the output terminal of the first shift register unit Re(n+1) of the (n+1)^{th} stage, Re(n+14) denotes a timing diagram of the signal on the output terminal of the first shift register unit Re(n+14) of the (n+14)^{th} stage, and GNn&(n+1) denotes a timing diagram of the signal on the output terminal of the second shift register unit GNn&(n+1) of the (n+1)/2^{th} stage, EMn&(n+1) denotes a timing diagram of the signal on the output terminal of the third shift register unit EMn&(n+1) of the (n+1)/2^{th} stage, GN(n+2)&(n+3) denotes a timing diagram of the signal on the output terminal of the second shift register unit (n+2)&(n+3) of the (n+3)/2^{th} stage, and EM(n+2)&(n+3) denotes a timing diagram of the signal on the output terminal of the third shift register unit EM(n+2)&(n+3) of the (n+3)/2^{th} stage.

The driving method of pixel driving circuit in the present disclosure may include a first reset stage, a second reset stage, a data writing stage, and a light-emitting stage.

Taking the n^{th} row of pixel driving circuits as an example, in the first reset stage t1 of the n^{th} row of pixel driving circuits, the first shift register unit Ren inputs a low level signal to the first reset signal terminals of the n^{th} row of pixel driving circuits, the second shift register unit GNn&(n+1) inputs a high level signal to the second gate driving signal terminals of the n^{th} row of pixel driving circuits, the first transistor T1 and the eighth transistor T8 are turned on, and the first initial signal terminal Vinit1 input a first initial signal to the gate electrode of the driving transistor T3. In the second reset stage t2, the first shift register unit Re(n+1) inputs a low level signal to the second reset signal terminals of the n^{th} row of pixel driving circuits, the second shift register unit GNn&(n+1) inputs a high level signal to the second gate driving signal terminals of the n^{th} row of pixel driving circuits, the seventh transistor T7 and the eighth transistor T8 are turned on, and the second initial signal terminal Vinit2 inputs a first initial signal to the second electrode of the seventh transistor T7. In the data writing stage t3, the first shift register unit Re(n+14) inputs a low level signal to the first gate driving signal terminals of the n^{th} of row pixel driving circuits, the second shift register unit GNn&(n+1) inputs a high level signal to the second gate driving signal terminals of the n^{th} row of pixel driving circuits, the eighth transistor T8, the fourth transistor T4 and the second transistor T2 are turned on, and the data signal terminal Da outputs a data signal to write a voltage Vdata+Vth to the gate electrode of the driving transistor, where Vdata is a voltage of the data signal and Vth is a threshold voltage of the driving transistor T3. In the light-emitting stage t4, the third shift register unit EMn&(n+1) inputs a low level signal to the enable signal terminals of the n^{th} row of the pixel driving circuits, the fifth transistor T5 and the sixth transistor T6 are turned on, and the driving transistor T3 drives the light-emitting unit OLED to emit light under the action of the voltage Vdata+Vth at the gate electrode thereof. According to the output current formula of the driving transistor I=(μWCox/2L)(Vgs−Vth)², where μ is the carrier mobility, Cox is the gate capacitance per unit area, W is the channel width of the driving transistor, L is the channel length of the driving transistor, Vgs is the gate-source voltage difference of the driving transistor, and Vth is the threshold voltage of the driving transistor, the output current of the driving transistor in the pixel driving circuit of the present disclosure is I=(μWCox/2L)(Vdata+Vth−Vdd−Vth)². The pixel driving circuit can avoid the impact of the threshold voltage of the driving transistor on the output current thereof.

An embodiment further provides a display panel, which may include a base substrate, a light-shielding layer, a first active layer, a first conductive layer, a second conductive layer, a second active layer, a third conductive layer, a fourth conductive layer, a fifth conductive layer and an electrode layer which are sequentially stacked, and an insulating layer may be provided between the above mentioned adjacent layers.

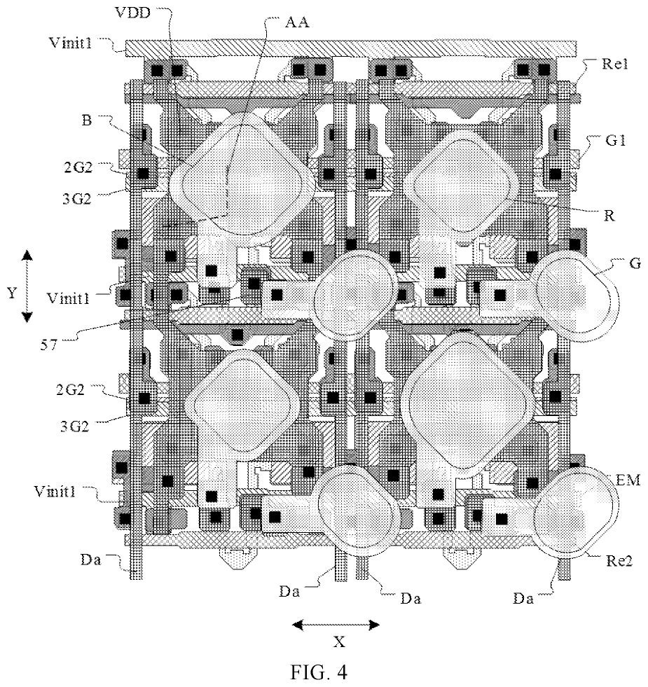

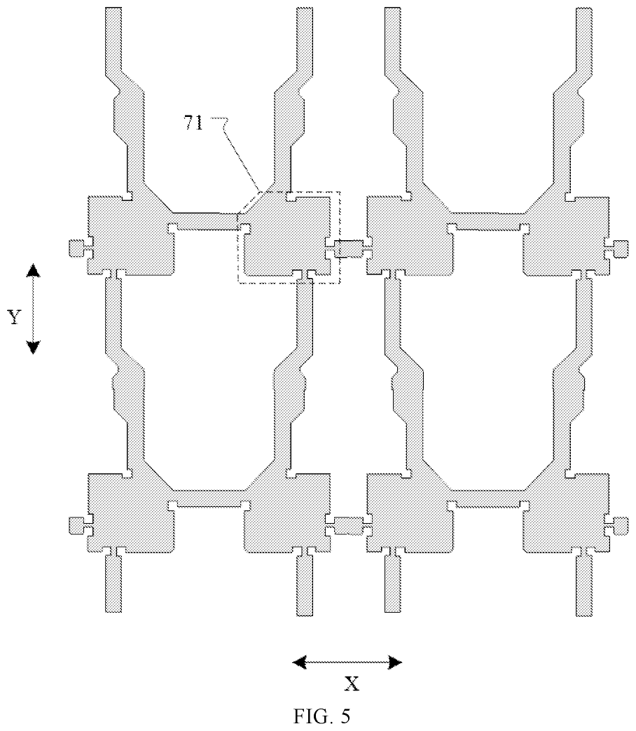

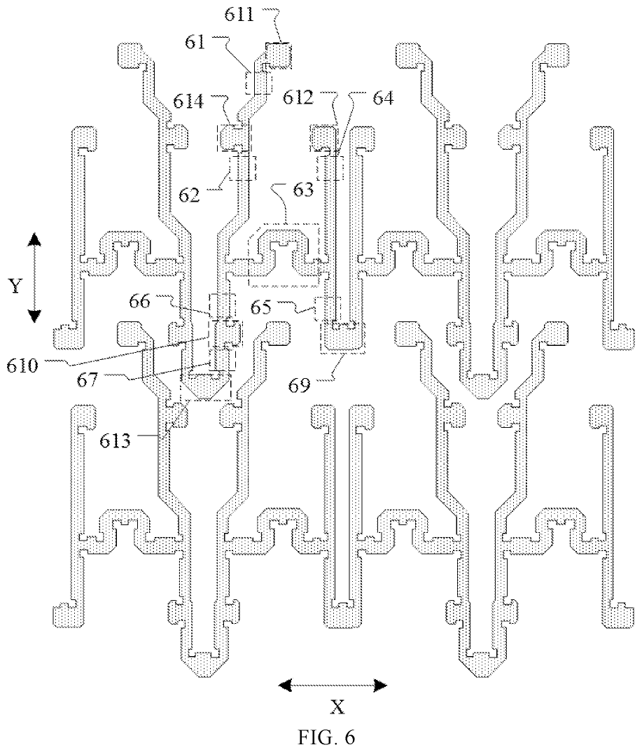

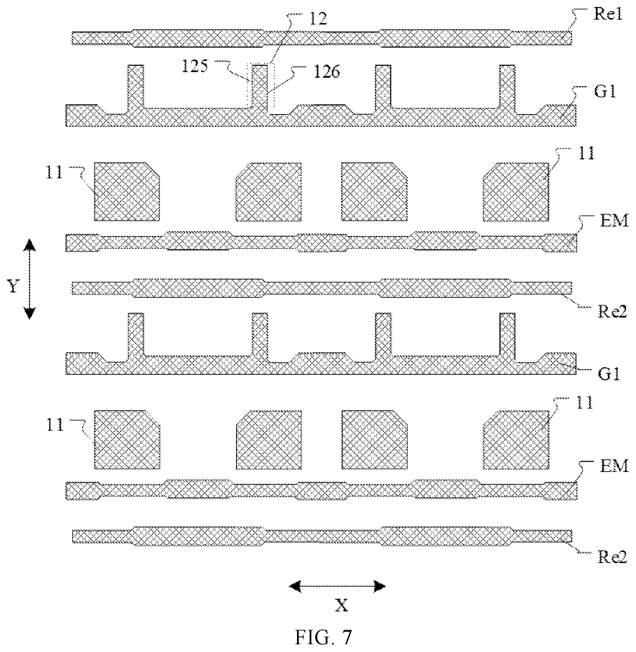

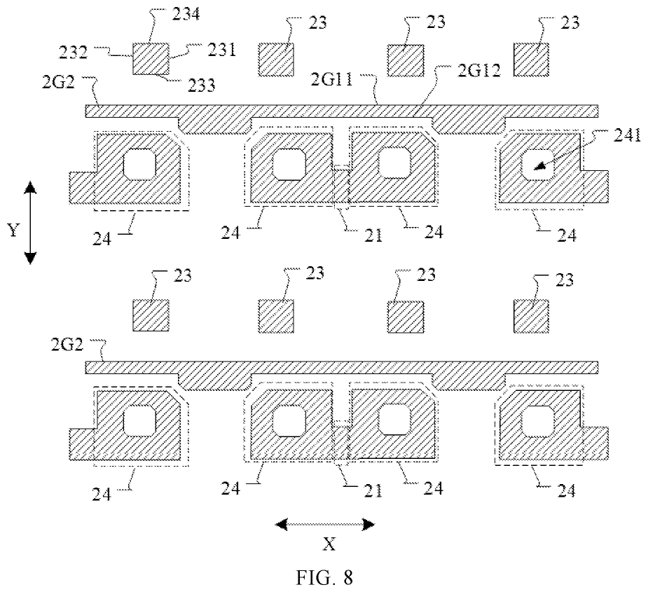

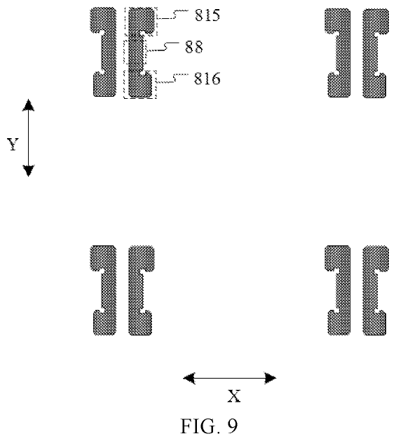

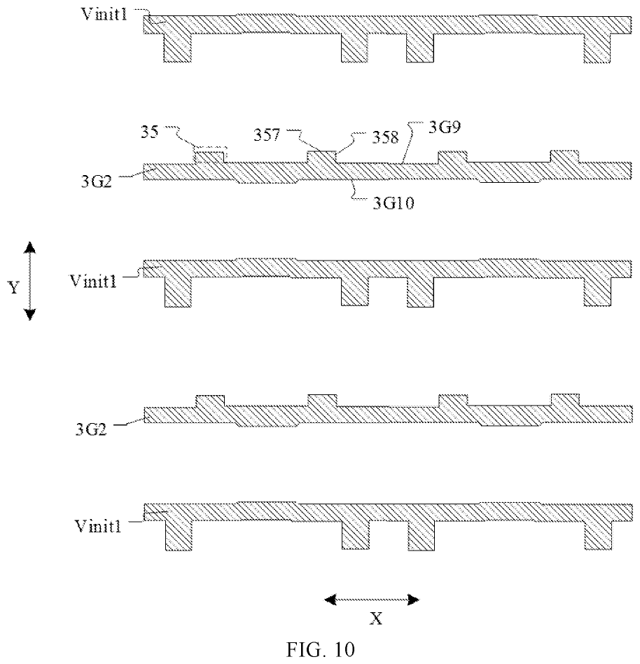

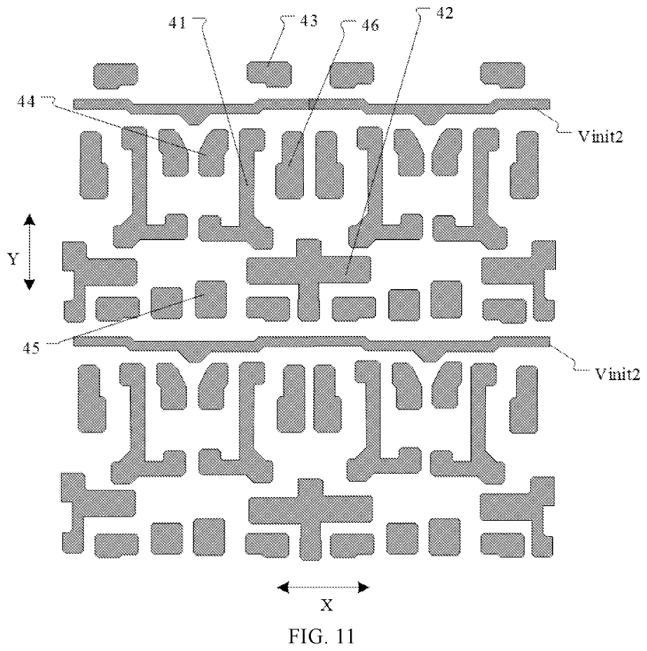

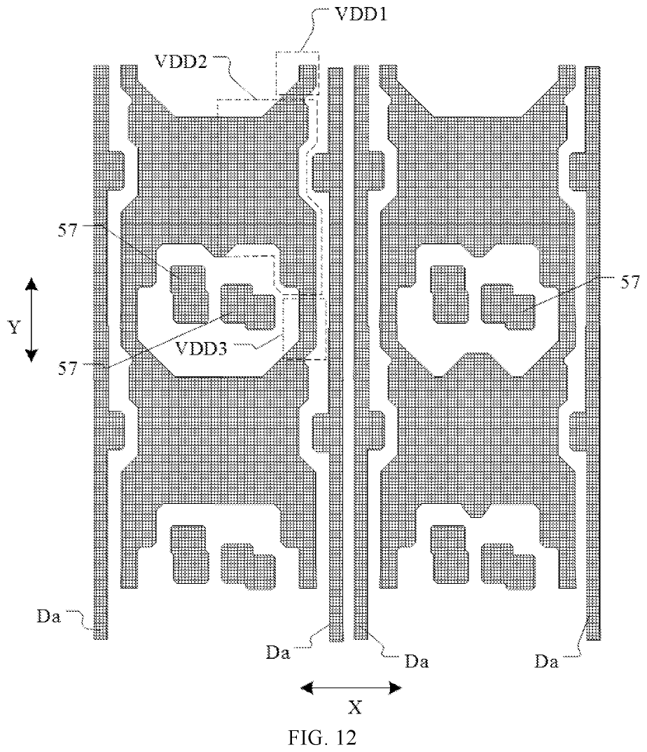

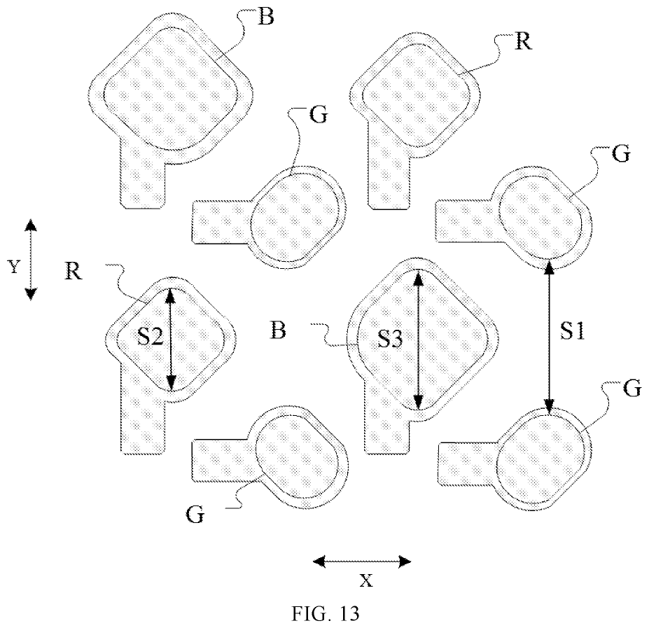

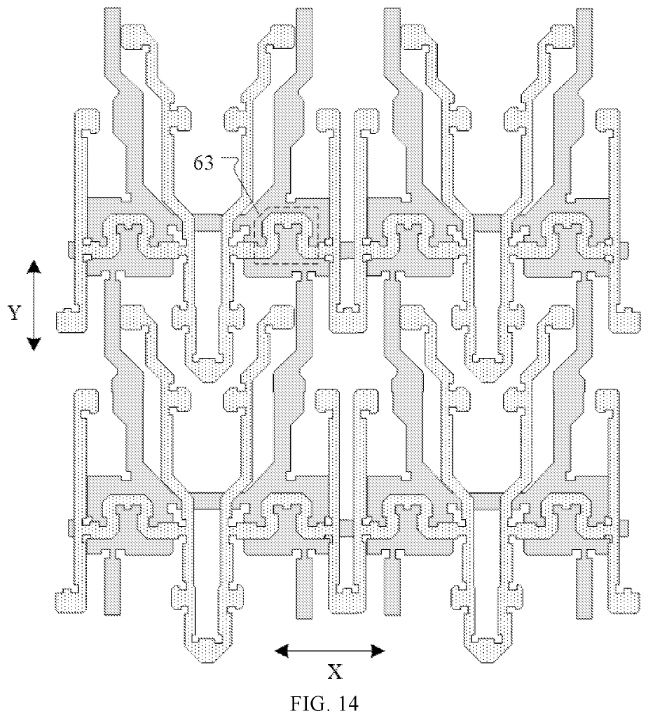

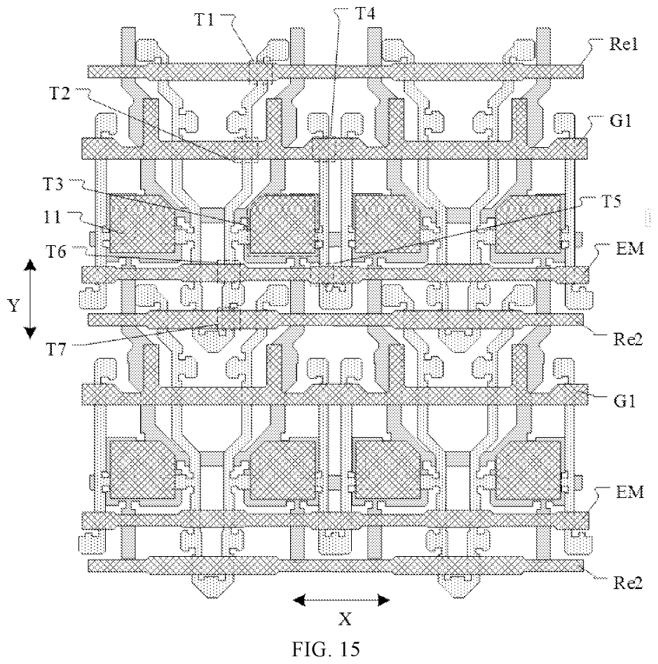

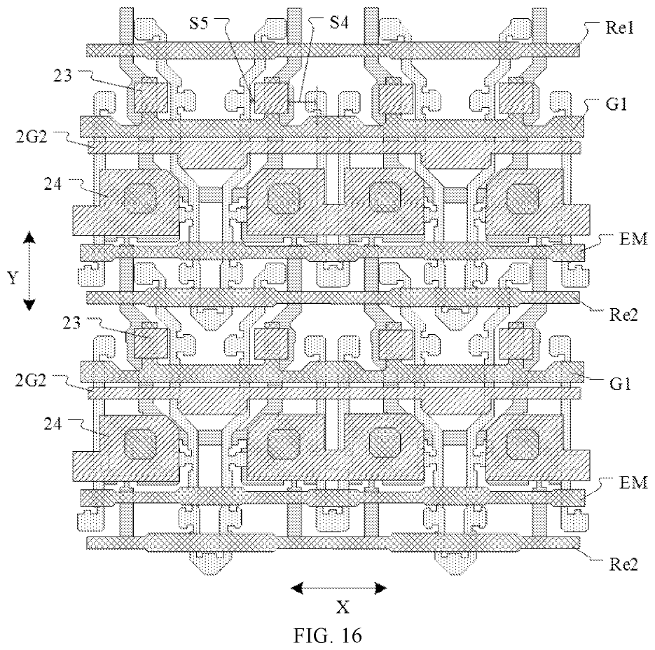

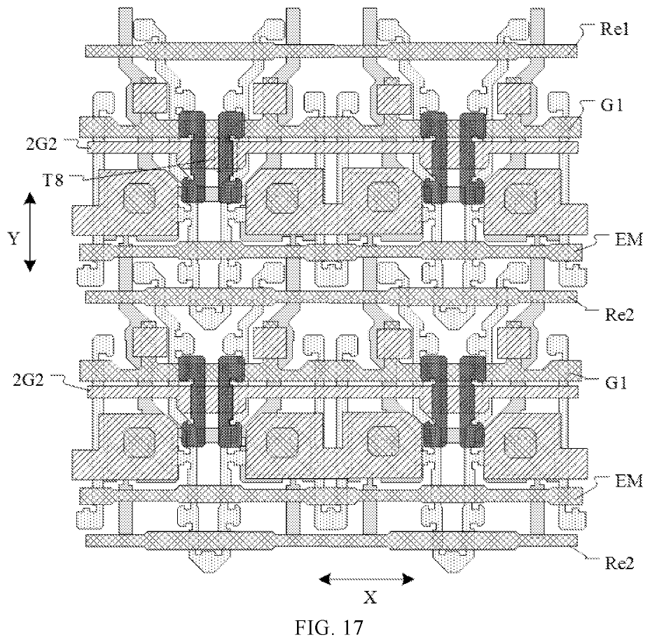

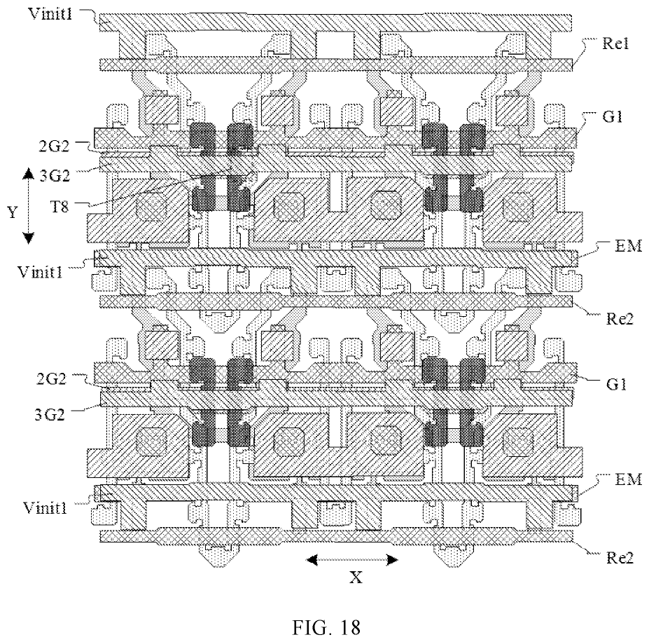

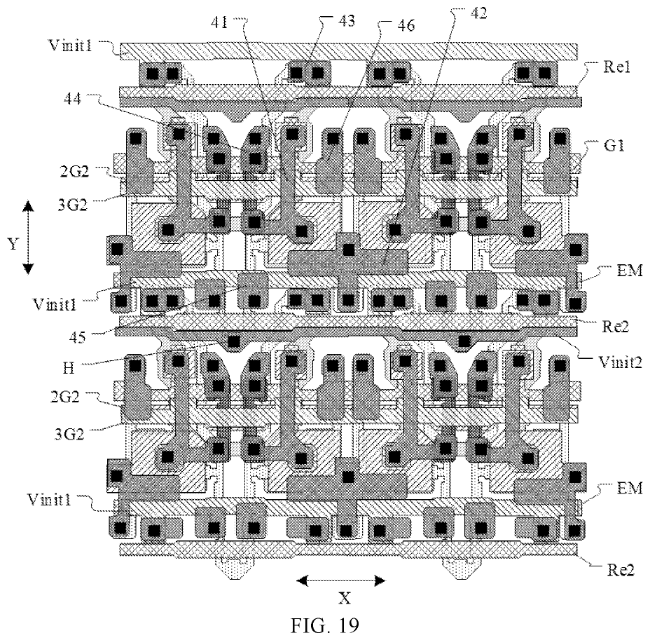

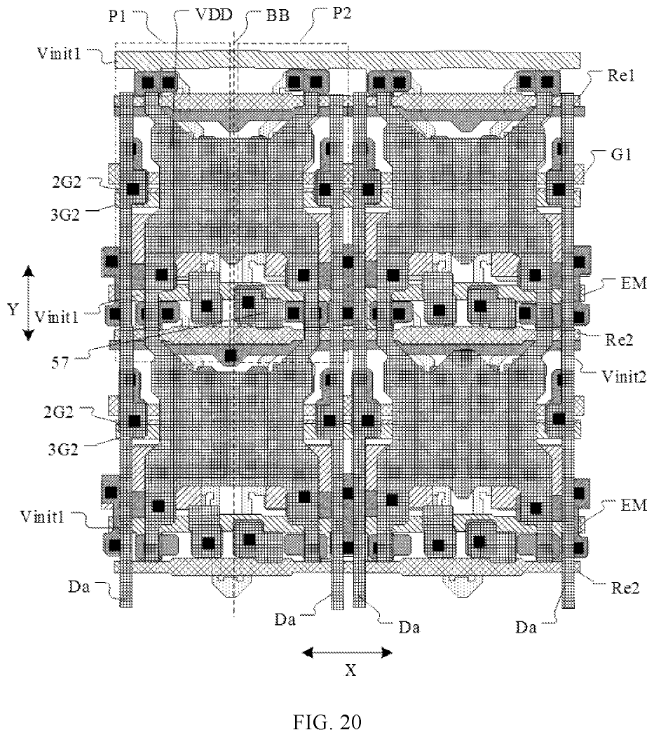

As shown in FIGS. 4 to 20, FIG. 4 is a structural layout of a display panel according to an embodiment of the present disclosure, FIG. 5 is a structural layout of a light-shielding layer in FIG. 4, FIG. 6 is a structural layout of a first active layer in FIG. 4, FIG. 7 is a structural layout of a first conductive layer in FIG. 4, FIG. 8 is a structural layout of a second conductive layer in FIG. 4, FIG. 9 is a structural layout of a second active layer in FIG. 4, FIG. 10 is a structural layout of a third conductive layer in FIG. 4, FIG. 11 is a structural layout of a fourth conductive layer in FIG. 4, FIG. 12 is a structural layout of a fifth conductive layer in FIG. 4, FIG. 13 is a structural layout of an electrode layer in FIG. 4, FIG. 14 is a structural layout of the light-shielding layer and the first active layer in FIG. 4, FIG. 15 is a structural layout of the light-shielding layer, the first active layer, and the first conductive layer in FIG. 4, FIG. 16 is a structural layout of the light-shielding layer, the first active layer, the first conductive layer, and the second conductive layer in FIG. 4, FIG. 17 is a structural layout of the light-shielding layer, the first active layer, the first conductive layer, the second conductive layer, and the second active layer in FIG. 4, FIG. 18 is a structural layout of the light-shielding layer, the first active layer, the first conductive layer, the second conductive layer, the second active layer, and the third conductive layer in FIG. 4, FIG. 19 is a structural layout of the light-shielding layer, the first active layer, the first conductive layer, the second conductive layer, the second active layer, the third conductive layer, and the fourth conductive layer in FIG. 4, and FIG. 20 is a structural layout of the light-shielding layer, the first active layer, the first conductive layer, the second conductive layer, the second active layer, the third conductive layer, the fourth conductive layer, and the fifth conductive layer in FIG. 4. The display panel may include a plurality of pixel driving circuits shown in FIG. 1. As shown in FIG. 20, the plurality of pixel driving circuits may include a first pixel driving circuit P1 and a second pixel driving circuit P2 arranged adjacent to each other in a first direction X. The first pixel driving circuit P1 and the second pixel driving circuit P2 may be provided in a mirrored and symmetrical manner with respect to a mirror symmetry plane BB. The mirror symmetry plane BB may be perpendicular to the base substrate. An orthographic projection of the first pixel driving circuit P1 on the base substrate and an orthographic projection of the second pixel driving circuit P2 on the base substrate may be provided symmetrically with respect to the intersection line between the mirror symmetry plane BB and the base substrate as a symmetry axis. The first pixel driving circuit P1 and the second pixel driving circuit P2 may form a repeating unit, and the display panel may include a plurality of repeating units arranged in an array in the first direction X and a second direction Y, where the first direction X may be a row direction and the second direction Y may be a column direction.

As shown in FIGS. 4, 5, 14, the light-shielding layer may include a plurality of light-shielding parts 71, and adjacent light-shielding parts 71 may be connected to each other.

As shown in FIGS. 4, 6, 15, the first active layer may include a first active part 61, a second active part 62, a third active part 63, a fourth active part 64, a fifth active part 65, a sixth active part 66, and a seventh active part 67. The first active part 61 is used to form a channel region of the first transistor T1, the second active part 62 is used to form a channel region of the second transistor T2, the third active part 63 is used to form a channel region of the driving transistor T3, the fourth active part 64 is used to form a channel region of the fourth transistor T4, the fifth active part 65 is used to form a channel region of the fifth transistor T5, the sixth active part 66 is used to form a channel region of the sixth transistor T6, and the seventh active part 67 is used to form a channel region of the seventh transistor T7. In addition, the first active layer may further include a ninth active part 69, a tenth active part 610, an eleventh active part 611, a twelfth active part 612, a thirteenth active part 613, and a fourteenth active part 614. The thirteenth active part 613 is connected to an end of the seventh active part 67 away from the sixth active part 66, and in the same repeating unit, two seventh active parts 67 are connected via the thirteenth active part 613. The tenth active part 610 is connected between the sixth active part 66 and the seventh active part 67. The eleventh active part 611 is connected to an end of the first active part 61 away from the second active part 62. The twelfth active part 612 is connected to an end of the fourth active part 64 away from the third active part 63. The ninth active part 69 is connected to an end of the fifth active part 65 away from the third active part 63, and in the repeating units adjacent to each other in the first direction, two fifth active parts 65 are connected via the ninth active part 69. The fourteenth active part 614 is connected between the first active part 61 and the second active part 62. An orthographic projection of the light-shielding part 71 on the base substrate may cover an orthographic projection of the third active part 63 on the base substrate, and the light-shielding part 71 may shade the third active part 63 to reduce the effect of light on the driving characteristics of the driving transistor T3. The first active layer may be formed from a polysilicon material, and accordingly, the first transistor T1, the second transistor T2, the driving transistor T3, the fourth transistor T4, the fifth transistor T5, the sixth transistor T6, and the seventh transistor T7 may be a P-type low-temperature polycrystalline silicon thin-film transistor.

As shown in FIGS. 4, 7, and 15, the first conductive layer may include a first reset signal line Re1, a first gate line G1, an enable signal line EM, a second reset signal line Re2, a first conductive part 11, and a second conductive part 12. An orthographic projection of the first reset signal line Re1 on the base substrate, an orthographic projection of the first gate line G1 on the base substrate, an orthographic projection of the enable signal line EM on the base substrate and an orthographic projection of the second reset signal line Re2 on the base substrate may all extend in the first direction X. In an embodiment, an orthographic projection of a certain structure on the base substrate extending in a certain direction may be understood that the orthographic projection of the structure on the base substrate extending in a straight line or windingly in the direction. The orthographic projection of the first reset signal line Re1 on the base substrate may cover the orthographic projection of the first active part 61 on the base substrate, a portion of the first reset signal line Re1 may be used to form the gate electrode of the first transistor T1, and the first reset signal line Re1 may be used to provide the first reset signal terminal in the pixel driving circuit shown in FIG. 1. The orthographic projection of the second reset signal line Re2 on the base substrate may cover the orthographic projection of the seventh active part 67 on the base substrate, a portion of the second reset signal line Re2 may be used to form the gate electrode of the seventh transistor T7, and the second reset signal line Re2 may be used to provide the second reset signal terminal in the pixel driving circuit shown in FIG. 1. The orthographic projection of the first gate line G1 on the base substrate may cover the orthographic projection of the second active part 62 on the base substrate and the orthographic projection of the fourth active part 64 on the base substrate, a portion of the first gate line G1 may be used to form the gate electrode of the second transistor T2, another portion of the first gate line G1 may be used to form the gate electrode of the fourth transistor T4, and the first gate line G1 may be used to provide the first gate driving signal terminal in the pixel driving circuit shown in FIG. 1. The orthographic projection of the enabling signal line EM on the base substrate may cover the orthographic projection of the fifth active part 65 on the base substrate and the orthographic projection of the sixth active part 66 on the base substrate, a portion of the enabling signal line EM may be used to form the gate electrode of the fifth transistor T5, another portion of the enabling signal line EM may be used to form the gate electrode of the sixth transistor T6, and the enabling signal line EM may be used to provide the enable signal terminal in the pixel driving circuit shown in FIG. 1. The orthographic projection of the first conductive part 11 on the base substrate may cover the orthographic projection of the third active part 63 on the base substrate, the first conductive part 11 may be used to form the gate electrode of the driving transistor T3, and in addition, the first conductive part 11 may be used to form the first electrode of the capacitor C. In an embodiment, the light-shielding layer may be formed from a conductive material, and the light-shielding layer may be connected to a stabilized voltage source, so that the light-shielding layer may shield the first conductive part 11 from the noise effects of external signals. In an embodiment, the orthographic projection of the enabling signal line EM on the base substrate may be located at a side, away from the orthographic projection of the first gate line G1 on the base substrate, of the orthographic projection of the first conductive part 11 on the base substrate, and the orthographic projection of the second reset signal line Re2 on the base substrate is located at a side, away from the orthographic projection of the first conductive part 11 on the base substrate, of the orthographic projection of the enabling signal line EM on the base substrate. The orthographic projection of the first reset signal line Re1 on the base substrate is located at a side, away from the orthographic projection of the first conductive part 11 on the base substrate, of the orthographic projection of the first gate line G1 on the base substrate. The second reset signal line Re2 in the pixel driving circuit of a previous row adjacent to a current row may be multiplexed as the first reset signal line Re1 in the pixel driving circuit of the current row, which arrangement may reduce the size of the pixel driving circuit in the second direction Y. In addition, in the display panel, a conducting process may be performed on the first active layer using the first conductive layer as a mask, i.e., a region of the first active layer covered by the first conductive layer may form a channel region of a transistor, and a region of the first active layer not covered by the first conductive layer may form a conductor structure.

As shown in FIGS. 4, 8, 16, the second conductive layer may include a third gate line 2G2, a third conductive part 23, a fourth conductive part 24, and a first connection part 21. An orthographic projection of the fourth conductive part 24 on the base substrate may be at least partially overlapped with the orthographic projection of the first conductive part 11 on the base substrate, and the fourth conductive part 24 may be used to form the second electrode of the capacitor C. Adjacent fourth conductive parts 24 in the repeating units adjacent in the first direction X are connected by the first connection part 21. An orthographic projection of the third conductive part 23 on the base substrate may be at least partially overlapped with an orthographic projection of the second conductive part 12 on the base substrate.

As shown in FIGS. 4, 9, and 17, the second active layer may include an eighth active part 88, a fifteenth active part 815, and a sixteenth active part 816, the eighth active part 88 is connected between the fifteenth active part 815 and the sixteenth active part 816, and the eighth active part 88 is used to form a channel region of the eighth transistor. An orthographic projection of the third gate line 2G2 on the base substrate may cover an orthographic projection of the eighth active part 88 on the base substrate, a portion of the third gate line 2G2 may be used to form a bottom gate electrode of the eighth transistor T8, and the third gate line 2G2 may be used to provide the second gate driving signal terminal in FIG. 1. The second active layer may be formed from indium gallium zinc oxide, and accordingly, the eighth transistor T8 may be an N-type metal oxide thin film transistor.

As shown in FIGS. 4, 10, and 18, the third conductive layer may include a second gate line 3G2 and a first initial signal line Vinit1, and an orthographic projection of the second gate line 3G2 on the base substrate and an orthographic projection of the first initial signal line Vinit1 on the base substrate may both extend along the first direction X. The orthographic projection of the second gate line 3G2 on the base substrate may cover the orthographic projection of the eighth active part 88 on the base substrate, and a portion of the second gate line 3G2 may be used to form a top gate electrode of the eighth transistor T8, and the second gate line 3G2 is used to provide the second gate driving signal terminal in FIG. 1. The orthographic projection of the second gate line 3G2 on the base substrate may be located between the orthographic projection of the first conductive part 11 on the base substrate and the orthographic projection of the first gate line G1 on the base substrate. The second gate line 3G2 and the third gate line 2G2 in the same row of pixel driving circuits may be connected through a via-hole, and the via-hole connected between the second gate line 3G2 and the third gate line 2G2 may be located in an edge wiring area outside the display area of the display panel. The first initial signal line Vinit1 may be used to provide the first initial signal terminal in FIG. 1. In an embodiment, the orthographic projection, on the base substrate, of the first initial signal line Vinit1 in the pixel driving circuits of a next row adjacent to a current row may be located between the orthographic projection, on the base substrate, of the second reset signal line Re2 in the pixel driving circuits of the current row and the orthographic projection, on the base substrate, of the first conductive part 11 in the pixel driving circuits of the current row, and the orthographic projection, on the base substrate, of the first initial signal line Vinit1 in the pixel driving circuits of the adjacent next row may be at least partially overlapped with the orthographic projection, on the base substrate, of the enable signal line EM in the pixel driving circuits of the current row. This arrangement may further reduce the size of the pixel driving circuit in the second direction Y. In addition, in the display panel, a conducting process may be performed on the second active layer using the third conductive layer as a mask, i.e., a region of the second active layer covered by the third conductive layer may form a channel region of a transistor, and a region of the second active layer not covered by the third conductive layer may form a conductor structure.

As shown in FIGS. 4, 11, 19, the fourth conductive layer may include a second initial signal line Vinit2, a first bridging part 41, a second bridging part 42, a third bridging part 43, a fourth bridging part 44, a fifth bridging part 45, and a sixth bridging part 46. An orthographic projection of the second initial signal line Vinit2 on the base substrate may extend in the first direction X, and the second initial signal line Vinit2 may be used to provide the second initial signal terminal in FIG. 1. The second initial signal line Vinit2 may be connected to the thirteenth active part 613 through a via-hole H to connect the second initial signal terminal and the first electrode of the seventh transistor T7. The black square indicates the position of the via-hole. The first bridging part 41 may be respectively connected to the first conductive part 11 and the sixteenth active part 816 through via-holes to connect the gate electrode of the driving transistor T3 and the first electrode of the eighth transistor T8. The fourth conductive part 24 is provided with an opening 241, and an orthographic projection, on the base substrate, of the via-hole connected to the first bridging part 41 and the first conductive part 11 falls within an orthographic projection of the opening 241 on the base substrate to avoid that the via-hole is connected to the fourth conductive part 24. The second bridging part 42 may be respectively connected to the first connection part 21 and the ninth active part 69 through via-holes to connect the second electrode of the capacitor and the first electrode of the fifth transistor T5. Adjacent pixel driving circuits in the repeating units adjacent in the first direction X may share the same second bridging part 42. The third bridging part 43 may be respectively connected to the eleventh active part 611 and the first initial signal line Vinit1 through via-holes to connect the first initial signal terminal and the first electrode of the first transistor. The fourth bridging part 44 may be respectively connected to the fifteenth active part 815 and the fourteenth active part 614 through via-holes to connect the second electrode of the eighth transistor to the second electrode of the first transistor and the first electrode of the second transistor. The fifth bridging part 45 may be connected to the tenth active part 610 through a via-hole to connect the second electrode of the sixth transistor T6 and the second electrode of the seventh transistor T7. The sixth bridging part 46 may be connected to the twelfth active part 612 through a via-hole to be connected to the first electrode of the fourth transistor.

In an embodiment, since the second conductive layer and the third conductive layer have a certain thickness, the insulating layer located on the side of the third gate line 2G2 away from the base substrate will be elevated at a position where the third gate line 2G2 is located, and the insulating layer located on the side of the second gate line 3G2 away from the base substrate will be elevated at a position where the second gate line 3G2 is located. At the overlapping position of the orthographic projection of the third gate line 2G2 on the base substrate with the orthographic projection of the second gate line 3G2 on the base substrate, there will be a relatively high elevation/bulge. As shown in FIG. 19, the orthographic projection of a portion of the first bridging part 41 on the base substrate is simultaneously overlapped with the orthographic projection of the second gate line 3G2 on the base substrate and the orthographic projection of the third gate line 2G2 on the base substrate, i.e., this portion of the first bridging part 41 may have a relatively high height, which may cause the first bridging part 41 to fracture. As shown in FIGS. 4, 10, 11, 18, 19, the third conductive layer may further include a fifth conductive part 35, the fifth conductive part 35 is connected to the second gate line 3G2, and an orthographic projection of the fifth conductive part 35 on the base substrate is located at a side, facing towards the orthographic projection of the first gate line G1 on the base substrate, of the orthographic projection of the second gate line 3G2 on the base substrate. The fifth conductive part 35 includes a seventh edge 357 away from the second gate line 3G2 and an eighth edge 358 connected to the seventh edge 357, and an orthographic projection of the seventh edge 357 on the base substrate extends in the first direction X. The second gate line 3G2 includes a ninth edge 3G9 and a tenth edge 3G10 provided opposite to each other in the second direction Y, an orthographic projection of the ninth edge 3G9 on the base substrate and an orthographic projection of the tenth edge 3G10 on the base substrate both extend in the first direction X, an orthographic projection of the ninth edge 3G9 on the base substrate is located at a side, facing towards the orthographic projection of the first gate line G1 on the base substrate, of an orthographic projection of the tenth edge 3G10 on the base substrate, the ninth edge 3G9 is connected to the eighth edge 358, and the angle between the orthographic projection of the eighth edge 358 on the base substrate and the orthographic projection of the ninth edge 3G9 on the base substrate is less than 180°, e.g., 90°. As shown in FIGS. 8, 16, the third gate line 2G2 includes an eleventh edge 2G11 and a twelfth edge 2G12 provided opposite to each other in the second direction Y, an orthographic projection of the eleventh edge 2G11 on the base substrate and an orthographic projection of the twelfth edge 2G12 on the base substrate both extend in the first direction X, and an orthographic projection of the eleventh edge 2G11 on the base substrate is located at a side, facing towards the orthographic projection of the first gate line G1 on the base substrate, of the orthographic projection of the twelfth edge 2G12 on the base substrate. As shown in FIG. 19, the orthographic projection of the first bridging part 41 on the base substrate intersects with the orthographic projection of the seventh edge 357 on the base substrate, the orthographic projection of the tenth edge 3G10 on the base substrate, the orthographic projection of the eleventh edge 2G11 on the base substrate, and the orthographic projection of the twelfth edge 2G12 on the base substrate. As shown in FIG. 18, a distance in the second direction Y between the orthographic projection of the seventh edge 357 on the base substrate and the orthographic projection of the eleventh edge 2G11 on the base substrate is greater than a distance in the second direction Y between the orthographic projection of the ninth edge 3G9 on the base substrate and the orthographic projection of the eleventh edge 2G11 on the base substrate. In the embodiment, the fifth conductive part 35 is additionally provided so that the seventh edge 357 has a large distance from the eleventh edge 2G11 in the second direction Y, and thus there may be a small slope between the seventh edge 357 and the eleventh edge 2G11, which in turn reduces the fracture risk of the first bridging part 41.

In an embodiment, as shown in FIG. 18, the orthographic projection of the seventh edge 357 on the base substrate may be located on the orthographic projection of the first gate line G1 on the base substrate, which arrangement may reduce the fracture risk of the first bridging part 41 by increasing the height of the position where the seventh edge 357 is located.

In an embodiment, as shown in FIG. 19, the orthographic projection, on the base substrate, of the second initial signal line Vinit2 in the pixel driving circuits of a previous row adjacent to a current row is located between the orthographic projection, on the base substrate, of the first reset signal line Re1 in the pixel driving circuits of the current row and the orthographic projection, on the base substrate, of the first gate line G1 in the pixel driving circuits of the current row, which arrangement may reduce the size of the pixel driving circuit in the second direction Y.

As shown in FIGS. 4, 12, and 20, the fifth conductive layer may include a data line Da, a power line VDD, and a seventh bridging part 57. Orthographic projections of the data line Da and the power line VDD on the base substrate may both extend along the second direction Y. The data line Da is used to provide the data signal terminal, and the power line VDD is used to provide the first power supply terminal. The data line Da may be connected to the sixth bridging part 46 through a via-hole to connect the first electrode of the fourth transistor T4 and the data signal terminal. The power supply terminal VDD may be connected to the second bridging part 42 through a via-hole to connect the first power supply terminal and the first electrode of the fifth transistor T5. The seventh bridging part 57 may be connected to the fifth bridging part 45 through a via-hole to be connected to the second electrode of the sixth transistor T6. The power line VDD may include a first extension part VDD1, a second extension part VDD2, and a third extension part VDD3. The second extension part VDD2 is connected between the first extension part VDD1 and the third extension part VDD3. A size, in the first direction X, of an orthographic projection of the second extension part VDD2 on the base substrate may be larger than a size, in the first direction X, of an orthographic projection of the first extension part VDD1 on the base substrate, and may be larger than a size, in the first direction X, of an orthographic projection of the third extension part VDD3 on the base substrate. The orthographic projection of the second extension part VDD2 on the base substrate may cover the orthographic projection of the eighth active part 88 on the base substrate, and the second extension part VDD2 may reduce the effect of light on the characteristics of the eighth transistor T8. The orthographic projection of the second extension part VDD2 on the base substrate may also cover the orthographic projection of the first bridging part 41 on the base substrate, and the second extension part VDD2 may have a voltage stabilization effect on the first bridging part 41 and shield the first bridging part 41 to reduce the voltage fluctuation of the gate electrode of the driving transistor T3 in the light-emitting stage. In the same repeating unit, the second extension parts VDD2 in the two power lines VDD may be connected to each other, so that the power line VDD and the fourth conductive part 24 may form a grid structure which reduces the voltage drop of the power supply signal thereon.

As shown in FIGS. 4, 13, the electrode layer may include a plurality of electrode parts: an R electrode part R, a G electrode part G, and a B electrode part B. Each of the electrode parts may be connected to the seventh bridging part 57 through a via-hole to be connected to the second electrode of the sixth transistor. Among the plurality of electrode parts connected to the same row of pixel driving circuits, the R electrode part, the G electrode part, the B electrode part, and the G electrode part are sequentially and alternately arranged in the row direction. Among two adjacent columns of pixel driving circuits, a plurality of R electrode parts and a plurality of B electrode parts are connected to one column of pixel driving circuits, the R electrode parts and the B electrode parts connected to the same column of pixel driving circuits are sequentially and alternately arranged in the column direction, and a plurality of G electrode parts are connected to the other column of pixel driving circuits. The orthographic projections, on the base substrate, of two G electrode parts connected to adjacent rows of pixel driving circuits and the same column of pixel driving circuits have a minimum distance S1 therebetween in the column direction which is larger than a size S2 in the column direction of the orthographic projection of the R electrode part on the base substrate or is larger than a size S3 in the column direction of the orthographic projection of the B electrode part on the base substrate. The orthographic projection of the R electrode part on the base substrate is coincided with an orthographic projection of a corresponding opening in the pixel definition layer on the base substrate, the orthographic projection of the G electrode part on the base substrate is coincided with an orthographic projection of a corresponding opening in the pixel definition layer on the base substrate, and the orthographic projection of the B electrode part on the base substrate is coincided with an orthographic projection of a corresponding opening in the pixel definition layer on the base substrate.

In an embodiment, as shown in FIGS. 4, 8, 11, 19, the first bridging part 41 may also be connected to the third conductive part 23 through a via-hole. As shown in FIG. 3, after the data writing stage of the pixel driving circuit is completed, the first gate line G1 makes the potential of the second conductive part 12 to be pulled up, and by the effect of the parallel-plate capacitive coupling formed by the third conductive part and the second conductive part 12, the third conductive part 23 is pulled up, that is, the gate voltage of the driving transistor is pulled up, so that the display panel may achieve a black frame display with a data signal of a lower voltage.

In an embodiment, as shown in FIG. 16, the orthographic projection of the second conductive part 12 on the base substrate may be located at a side, away from the orthographic projection of the first conductive part 11 on the base substrate, of the orthographic projection of the first gate line G1 on the base substrate, and the orthographic projection of the third conductive part 23 on the base substrate may be located at a side, away from the orthographic projection of the first conductive part 11 on the base substrate, of the orthographic projection of the first gate line G1 on the base substrate. In the first direction X, the orthographic projection of the second conductive part 12 on the base substrate and the orthographic projection of the third conductive part 23 on the base substrate may be both located between the orthographic projection of the second active part 62 on the base substrate and the orthographic projection of the fourth active part 64 on the base substrate. A distance S4 in the first direction X between the orthographic projection of the third conductive part 23 on the base substrate and the orthographic projection of the fourth active part 64 on the base substrate may be greater than a distance S5 in the first direction X between the orthographic projection of the third conductive part 23 on the base substrate and the orthographic projection of the second active part 62 on the base substrate. The distance in the first direction X between the orthographic projection of the third conductive part 23 on the base substrate and the orthographic projection of the fourth active part 64 on the base substrate may refer to the distance in the first direction X between the adjacent edges of the orthographic projection of the third conductive part 23 on the base substrate and the orthographic projection of the fourth active part 64 on the base substrate, and similarly, the distance in the first direction X between the third conductive part 23 on the base substrate and the orthographic projection of the second active part 62 on the base substrate may refer to the distance in the first direction X between the adjacent edges of the orthographic projection of the third conductive part 23 on the base substrate and the orthographic projection of the second active part 62 on the base substrate. Since the fourth active part 64 needs to be connected to the data line Da, in an embodiment, the third conductive part 23 is provided at a side away from the fourth active part 64, so that the noise effect of the data line Da or the equipotential point of the data line Da on the gate electrode of the driving transistor may be reduced.

In an embodiment, as shown in FIGS. 7, 8, and 16, the third conductive part 23 may include a first edge 231 and a second edge 232 provided opposite to each other in the first direction X, and a third edge 233 and a fourth edge 234 provided opposite to each other in the second direction Y. The second conductive part 12 includes a fifth edge 125 and a sixth edge provided opposite to each other in the first direction X. In the first direction X, the orthographic projection of the fifth edge 125 on the base substrate is located between the orthographic projection of the first edge 231 on the base substrate and the orthographic projection of the second edge 232 on the base substrate, the orthographic projection of the sixth edge 126 on the base substrate is located between the orthographic projection of the first edge 231 on the base substrate and the orthographic projection of the second edge 232 on the base substrate, and the orthographic projection of the third edge 233 on the base substrate and the orthographic projection of the fourth edge 234 on the base substrate both intersect with the orthographic projection of the second conductive part 12 on the base substrate.

It is to be understood that the second conductive part and the third conductive part may also be provided in other conductive layers, and that the second conductive part and the third conductive part may be provided in any conductive layer between the second conductive layer and the fourth conductive layer. For example, the third conductive part may also be provided in the second active layer or the third conductive layer. Compared to providing the third conductive part in the second active layer, in an embodiment, the third conductive part is provided in the second conductive layer, which can reduce the distance between the second conductive part and the third conductive part, and thus may increase the capacitance value of the parasitic capacitance formed by the second conductive part and the third conductive part, increase the pull-up effect of the first gate line G1 on the gate electrode of the driving transistor T3, and in turn, reduce the data signal voltage required for the black frame display of the display panel. In addition, in an embodiment, the third conductive part is provided in the second conductive layer which is farther away from the layer where the data line Da is located, so that the noise effect of the data line on the gate electrode of the driving transistor T3 may be reduced. As shown in the table below, Table 1 shows simulation data of the display panel when the third conductive part is provided in the second active layer, and Table 2 shows the simulation data of the display panel when the third conductive part is provided in the second conductive layer. Cx1 denotes the capacitance value of the parasitic capacitance between the equipotential structure of the first gate line and the equipotential structure of the gate electrode of the driving transistor, and Cx2 denotes the capacitance value of the parasitic capacitance between the equipotential structure of the data line and the equipotential structure of the gate electrode of the driving transistor. Normal denotes the normal driving mode of the display panel, HBM denotes the high brightness driving mode of the display panel, Vdata@L0 denotes the data signal voltage required for each sub-pixel in the state of a black frame, R denotes the red sub-pixel, G denotes the green sub-pixel, and B denotes the blue sub-pixel. V_Crosstalk denotes the ratio of the variable of the output current of the driving transistor under the noise effect of the data line to the output current of the driving transistor in the ideal state.

TABLE 1

| | | | Vdata@L0 | | | |
|---|---|---|---|---|---|---|
| Cx1(fF) | Cx2(aF) | | R | G | B | V_Crosstalk |
| 7.198 | 600 | Normal | 6.34 | 6.37 | 6.19 | 2.16% |
| | | HBM | 6.60 | 6.70 | 6.55 | |

TABLE 2

| | | | Vdata@L0 | | | |
|---|---|---|---|---|---|---|
| Cx1(fF) | Cx2(aF) | — | R | G | B | V_Crosstalk |
| 14.209 | 160 | Normal | 5.33 | 5.39 | 5.21 | 0.59% |
| | | HBM | 5.65 | 5.7 | 5.54 | |

According to the above tables, it can be further verified that providing the third conductive part in the second conductive layer may increase the capacitance value of the parasitic capacitance formed by the second conductive part and the third conductive part, thereby reducing the data signal voltage required for the black frame display of the display panel. In addition, the above table verifies that providing the third conductive part in the second conductive layer that is farther away from the layer where the data line Da is located may reduce the noise effect of the data line on the gate electrode of the driving transistor T3.

It is to be understood that in other embodiments, the arrangement of additionally providing the second conductive part and the third conductive part to synchronously couple the driving transistor gate through the first gate line G1 can also be applied in other pixel driving circuit structures or other display panel layout structures. For example, the arrangement may also be applied to the circuit architecture of the N-type driving transistor, and accordingly, the first gate line G1 may synchronously pull down the third conductive part after the data writing stage is completed to pull down the gate voltage of the driving transistor.

It should be noted that, as shown in FIGS. 4, 19, and 20, the black squares drawn on the side of the fourth conductive layer away from the base substrate denote the via-holes for the fourth conductive layer connecting to the other layers at a side thereof facing towards the base substrate; the black squares drawn on the side of the fifth conductive layer away from the base substrate denote the via-holes for the fifth conductive layer connecting to the other layers at a side thereof facing towards the base substrate; and the black squares drawn on the side of the electrode layer away from the base substrate denote the via-holes for the electrode layer connecting to the other layers at a side thereof facing towards the base substrate. The black squares indicate only the positions of the via-holes, and different via-holes indicated by different positions of the black squares may run through different insulating layers.

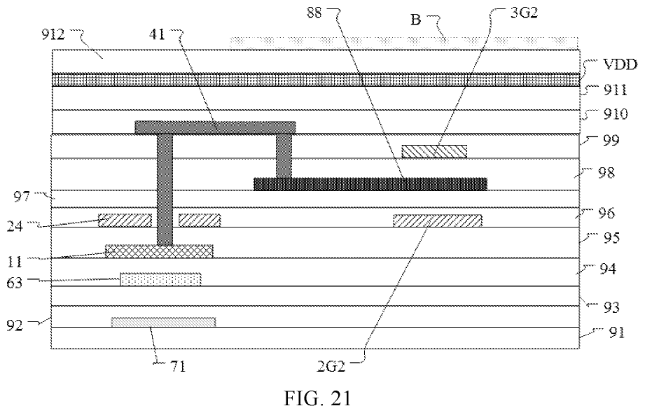

As shown in FIG. 21, FIG. 21 is a partial sectional view of the display panel shown in FIG. 4 taken along a dashed line AA. The display panel may further include a blocking layer 92, a first buffer layer 93, a first insulating layer 94, a second insulating layer 95, a first dielectric layer 96, a second buffer layer 97, a third insulating layer 98, a second dielectric layer 99, a passivation layer 910, a first planarization layer 911, and a second planarization layer 912. The base substrate 91, the light-shielding layer, the blocking layer 92, the first buffer layer 93, the first active layer, the first insulating layer 94, the first conductive layer, the second insulating layer 95, the second conductive layer, the first dielectric layer 96, the second buffer layer 97, the second active layer, the third insulating layer 98, the third conductive layer, the second dielectric layer 99, the fourth conductive layer, the passivation layer 910, the first planarization layer 911, the fifth conductive layer, the second planarization layer 912, and the electrode layer are stacked sequentially. The base substrate may include a first polyimide layer, a second blocking layer, a second polyimide layer, and a third blocking layer stacked sequentially, and the light-shielding layer is provided on a side of the third blocking layer away from the first polyimide layer. The first polyimide layer may have a thickness of 8-12 um, for example, the thickness of the first polyimide layer may be 8 um, 10 um, 12 um. The second blocking layer may include an amorphous silicon layer and a silicon oxide layer, and a thickness of the amorphous silicon layer in the second blocking layer may be 30 Å-50 Å, for example, the thickness of the amorphous silicon layer may be 30 Å, 40 Å, 50 Å, and a thickness of the silicon oxide layer in the second blocking layer may be 5000 Å-7000 Å, for example, the thickness of the silicon oxide layer may be 5000 Å, 6000 Å, 7000 Å. A thickness of the second polyimide layer may be 4 um-7 um, for example, the thickness of the second polyimide layer may be 4 um, 5 um, 5.8 um, 7 um. The third blocking layer may include a silicon oxide layer, which may have a thickness of 500 Å-1500 Å, for example, the thickness of the silicon oxide layer may be 500 Å, 1000 Å, 1500 Å. The light-shielding layer may include a molybdenum layer, which have a thickness of 500 Å-1500 Å, for example, the molybdenum layer may have a thickness of 500 Å, 1000 Å, 1500 Å. The blocking layer 92 may include a silicon oxide layer, which may have a thickness of 3000 Å-5000 Å, for example, the silicon oxide layer may have a thickness of 3000 Å, 4000 Å, 5000 Å. The first buffer layer 93 may include a silicon oxide layer and a silicon nitride layer, the silicon oxide layer may have a thickness of 2000 Å-4000 Å, for example, the silicon oxide layer may have a thickness of 2000 Å, 3000 Å, 4000 Å, and the silicon nitride layer may have a thickness of 500 Å-1500 Å, for example, the silicon nitride layer may have a thickness of 500 Å, 1000 Å, 1500 Å. The first active layer may include a polysilicon layer, and the thickness of the polysilicon layer may be 300 Å-700 Å, for example, the thickness of the polysilicon layer may be 300 Å, 500 Å, 700 Å. The first insulating layer 94 may include a silicon oxide layer, which may have a thickness of 1000 Å-1500 Å, for example, the silicon oxide layer may have a thickness of 1000 Å, 1200 Å, 1500 Å. The first conductive layer may include a molybdenum layer, which may have a thickness of 2000 Å-4000 Å, for example, the molybdenum layer may have a thickness of 2000 Å, 3000 Å, 4000 Å. The second insulating layer 95 may include a silicon nitride layer, which may have a thickness of 1000 Å-1500 Å, for example, the silicon nitride layer may have a thickness of 1000 Å, 1300 Å, 1500 Å. The second conductive layer may have the same structure as the first conductive layer. The first dielectric layer 96 may include a silicon nitride layer, and the thickness of the silicon nitride layer may be 500 Å-1500 Å, for example, the thickness of the silicon nitride layer may be 500 Å, 1000 Å, 1500 Å. The second buffer layer 97 may include a silicon oxide layer, which may have a thickness of 2000 Å-4000 Å, for example, the silicon oxide layer may have a thickness of 2000 Å, 3000 Å, 4000 Å. The second active layer may have a thickness of 200 Å-400 Å, for example, the second active layer may have a thickness of 200 Å, 310 Å, 400 Å. The third insulating layer 98 may include a silicon oxide layer, which may have a thickness of 1200 Å-1700 Å, for example, the silicon oxide layer may have a thickness of 1200 Å, 1500 Å, 1700 Å. The third conductive layer may include a molybdenum layer and a titanium nitride layer, the molybdenum layer may have a thickness of 2000 Å-3000 Å, for example, the molybdenum layer may have a thickness of 2000 Å, 2500 Å, 3000 Å, and the titanium nitride layer may have a thickness of 200 Å-400 Å, for example, the titanium nitride layer may have a thickness of 200 Å, 300 Å, 400 Å. The second dielectric layer 99 may include a silicon nitride layer and a silicon oxide layer, the thickness of the silicon nitride layer may be 1500 Å-2500 Å, for example, the thickness of the silicon nitride layer may be 1500 Å, 2000 Å, 2500 Å, and the thickness of the silicon oxide layer may be 2500 Å-3500 Å, for example, the thickness of the silicon oxide layer may be 2500 Å, 3000 Å, 3500 Å. The fourth conductive layer may include a first titanium layer, an aluminium layer, and a second titanium layer stacked in sequence, the thickness of the first titanium layer may be 400 Å-700 Å, for example, the thickness of the first titanium layer may be 400 Å, 550 Å, 700 Å, the thickness of the aluminium layer may be 5000 Å-7000 Å, for example, the thickness of the aluminium layer may be 5000 Å, 6000 Å, 7000 Å, the thickness of the second titanium layer may have a thickness of 400 Å-700 Å, for example, the second titanium layer may have a thickness of 400 Å, 500 Å, 700 Å. The passivation layer 910 may include a silicon oxide layer, which may have a thickness of 2000 Å-4000 Å, for example, the silicon oxide layer may have a thickness of 2000 Å, 3000 Å 4000 Å. The first planarization layer 911 may include a polyimide layer, which may have a thickness of 1 um-2 um, for example, the polyimide layer may have a thickness of 1 um, 1.5 um, 2 um. The structure of the fifth conductive layer may be the same as the structure of the fourth conductive layer. The structure of the second planarization layer 912 may be the same as the structure of the first planarization layer 911. The electrode layer may include a first indium tin oxide layer, a silver layer, and a second indium tin oxide layer provided in sequence, the thickness of the first indium tin oxide layer may be 50 Å-90 Å, for example, the thickness of the first indium tin oxide layer may be 50 Å, 70 Å, 90 Å, the thickness of the silver layer may be 700 Å-1000 Å, for example, the thickness of the silver layer may be 700 Å, 850 Å, 1000 Å, and the second indium tin oxide layer may have a thickness of 40 Å-80 Å, for example, the second indium tin oxide layer may have a thickness of 40 Å, 60 Å, 80 Å. The display panel may further include a pixel defining layer provided on a side of the electrode layer away from the base substrate, the pixel defining layer may include a polyimide layer, and the thickness of the polyimide layer may be 1.5 um-3 um, for example, the thickness of the polyimide layer may be 1.5 um, 2.1 um, 3 um.

It is to be noted that the scale of the accompanying drawings in the present disclosure may be used as a reference in the actual process, which however is not limited thereto, for example, the width-to-length ratio of the channel, the thicknesses and spacings of the respective film layers, and the widths and spacings of the respective signal lines may be adjusted according to the actual needs. The number of pixels in the display panel and the number of sub-pixels in each pixel are also not limited to the number shown in the drawings, and the accompanying drawings depicted in the present disclosure are only schematic diagrams of the structure. Furthermore, the qualifiers such as first, second, and the like are only used to qualify different structure names, which do not have a meaning of a particular order.

An embodiment also provides a display device including the display panel as described above. The display device may be a display device such as a mobile phone, a tablet computer, a television, and the like.

Those skilled in the art may easily conceive of other embodiments of the present disclosure upon consideration of the specification and practice of what is disclosed herein. The present application is intended to cover any variations, uses, or adaptations of the present disclosure that follow the general principles of the present disclosure and include the common knowledge or the customary technical means in the art not disclosed herein. The specification and embodiments are to be regarded as exemplary only, and the true scope and spirit of the present disclosure is indicated by the claims.

It is to be understood that the present disclosure is not limited to the precise structure which has been described above and illustrated in the accompanying drawings, and that various modifications and changes may be made without departing from the scope thereof. The scope of the present disclosure is limited only by the appended claims.

1. A display panel comprising a pixel driving circuit, wherein the pixel driving circuit comprises a driving transistor and a fourth transistor, the fourth transistor comprises a first electrode connected to a data line and a second electrode connected to a first electrode of the driving transistor, and the display panel further comprises:
a base substrate;
a first conductive layer provided on a side of the base substrate and comprising a first gate line and a first conductive part, an orthographic projection, on the base substrate, of the first gate line extending in a first direction, a portion of the first gate line being configured to form a gate electrode of the fourth transistor, and the first conductive part being configured to form a gate electrode of the driving transistor;
a second conductive part connected to the first gate line;
a third conductive part provided in a different conductive layer from the second conductive part, an orthographic projection, on the base substrate, of the third conductive part being at least partially overlapped with an orthographic projection, on the base substrate, of the second conductive part; and
a fourth conductive layer provided on a side, away from the base substrate, of the first conductive layer and comprising a first bridging part, the first bridging part being connected to the third conductive part and the first conductive part through via-holes respectively.

2. The display panel according to claim 1, wherein the pixel driving circuit further comprises an eighth transistor, a first transistor, and a second transistor,
the eighth transistor comprises a first electrode connected to the gate electrode of the driving transistor and a second electrode connected to a second electrode of the first transistor, the first transistor comprises a first electrode connected to a first initial signal line, and the second transistor comprises a first electrode connected to the second electrode of the eighth transistor and a second electrode connected to the second electrode of the driving transistor.

3. The display panel according to claim 1, wherein a conductive layer in which the second conductive part is located is provided in the first conductive layer or between the first conductive layer and the fourth conductive layer, and
a conductive layer in which the third conductive part is located is provided between the conductive layer in which the second conductive part is located and the fourth conductive layer.

4. The display panel according to claim 3, wherein the pixel driving circuit further comprises a capacitor, the capacitor comprises a first electrode connected to the gate electrode of the driving transistor and a second electrode connected to a power line, and the first conductive part is further configured to form the first electrode of the capacitor,
the display panel further comprises a second conductive layer, and the second conductive layer is provided between the first conductive layer and the fourth conductive layer, and comprises:
a fourth conductive part having an orthographic projection on the base substrate at least partially overlapped with an orthographic projection, on the base substrate, of the first conductive part, the fourth conductive part being configured to form the second electrode of the capacitor, and
wherein the third conductive part is provided in the second conductive layer.

5. The display panel according to claim 2, wherein the display panel further comprises:
a second active layer provided between the first conductive layer and the fourth conductive layer and comprising an eighth active part, the eighth active part being configured to form a channel region of the eighth transistor, and
wherein the third conductive part is provided in the second active layer.

6. The display panel according to claim 1, wherein the orthographic projection, on the base substrate, of the second conductive part is located at a side, away from an orthographic projection of the first conductive part on the base substrate, of the orthographic projection, on the base substrate, of the first gate line, and
the orthographic projection, on the base substrate, of the third conductive part is located at a side, away from the orthographic projection of the first conductive part on the base substrate, of the orthographic projection, on the base substrate, of the first gate line.

7. The display panel according to claim 1, wherein the pixel driving circuit further comprises a second transistor, the second transistor comprises a first electrode connected to the gate electrode of the driving transistor and a second electrode connected to the second electrode of the driving transistor, and a portion of the first gate line is configured to form a gate electrode of the second transistor,
the display panel further comprises:
a first active layer provided between the base substrate and the first conductive layer and comprising a second active part and a fourth active part, the orthographic projection, on the base substrate, of the first gate line covering an orthographic projection, on the base substrate, of the second active part and an orthographic projection, on the base substrate, of the fourth active part, the second active part being configured to form a channel region of the second transistor, and the fourth active part being configured to forming a channel region of the fourth transistor, and
wherein in the first direction, the orthographic projection, on the base substrate, of the second conductive part is located between the orthographic projection, on the base substrate, of the second active part and the orthographic projection, on the base substrate, of the fourth active part.

8. The display panel according to claim 7, wherein in the first direction, the orthographic projection, on the base substrate, of the third conductive part is located between the orthographic projection, on the base substrate, of the second active part and the orthographic projection, on the base substrate, of the fourth active part, and
a distance in the first direction between the orthographic projection, on the base substrate, of the third conductive part and the orthographic projection, on the base substrate, of the fourth active part is greater than a distance in the first direction between the orthographic projection, on the base substrate, of the third conductive part and the orthographic projection, on the base substrate, of the second active part.

9. The display panel according to claim 6, wherein the third conductive part comprises a first edge and a second edge provided opposite to each other in the first direction, and a third edge and a fourth edge provided opposite to each other in a second direction intersecting the first direction,
the second conductive part comprises a fifth edge and a sixth edge provided opposite to each other in the first direction,
in the first direction, an orthographic projection, on the base substrate, of the fifth edge is located between an orthographic projection, on the base substrate, of the first edge and an orthographic projection, on the base substrate, of the second edge, and an orthographic projection, on the base substrate, of the sixth edge is located between the orthographic projection, on the base substrate, of the first edge and the orthographic projection, on the base substrate, of the second edge, and
both of an orthographic projection, on the base substrate, of the third edge, and an orthographic projection, on the base substrate, of the fourth edge intersect with the orthographic projection, on the base substrate, of the second conductive part.

10. The display panel according to claim 2, wherein the display panel further comprises:
a second active layer provided between the first conductive layer and the fourth conductive layer and comprising an eighth active part, the eighth active part being configured to form a channel region of the eighth transistor; and
a third conductive layer provided between the second active layer and the fourth conductive layer and comprising a second gate line, an orthographic projection, on the base substrate, of the second gate line extending in the first direction and covering an orthographic projection, on the base substrate, of the eighth active part, and a portion of the second gate line being configured to form a top gate electrode of the eighth transistor,
wherein the orthographic projection, on the base substrate, of the second gate line is located between an orthographic projection, on the base substrate, of the first conductive part and the orthographic projection, on the base substrate, of the first gate line.

11. The display panel according to claim 10, wherein the display panel further comprises:
a second conductive layer provided between the first conductive layer and the second active layer and comprising a third gate line, an orthographic projection, on the base substrate, of the third gate line extending in the first direction and covering the orthographic projection, on the base substrate, of the eighth active part, and a portion of the third gate line being configured to form a bottom gate electrode of the eighth transistor,
the third conductive layer further comprises a fifth conductive part, the fifth conductive part is connected to the second gate line, and has an orthographic projection on the base substrate located at a side, facing towards the orthographic projection of the first gate line on the base substrate, of the orthographic projection, on the base substrate, of the second gate line, the fifth conductive part comprises a seventh edge away from the second gate line and an eighth edge connected to the seventh edge, and the seventh edge has an orthographic projection on the base substrate extending in the first direction and intersecting with an orthographic projection, on the base substrate, of the eighth edge,
the second gate line comprises a ninth edge and a tenth edge provided opposite to each other in a second direction intersecting with the first direction, an orthographic projection, on the base substrate, of the ninth edge and an orthographic projection, on the base substrate, of the tenth edge both extend in the first direction, the orthographic projection, on the base substrate, of the ninth edge is located at a side, facing towards the orthographic projection of the first gate line on the base substrate, of the orthographic projection, on the base substrate, of the tenth edge, the ninth edge is connected to the eighth edge, an angle between the orthographic projection, on the base substrate, of the eighth edge and the orthographic projection, on the base substrate, of the ninth edge is less than 180°,
the third gate line comprises an eleventh edge and a twelfth edge provided opposite to each other in the second direction, an orthographic projection, on the base substrate, of the eleventh edge and an orthographic projection, on the base substrate, of the twelfth edge both extend in the first direction, and the orthographic projection, on the base substrate, of the eleventh edge is located at a side, facing towards the orthographic projection of the first gate line on the base substrate, of the orthographic projection, on the base substrate, of the twelfth edge,
an orthographic projection, on the base substrate, of the first bridging part is overlapped with the orthographic projection, on the base substrate, of the seventh edge, the orthographic projection, on the base substrate, of the tenth edge, the orthographic projection, on the base substrate, of the eleventh edge, and the orthographic projection, on the base substrate, of the twelfth edge,
an orthographic projection, on the base substrate, of a portion of the first bridging part is overlapped with both of the orthographic projection, on the base substrate, of the second gate line and the orthographic projection, on the base substrate, of the third gate line.

12. The display panel according to claim 11, wherein
a distance in the second direction between the orthographic projection, on the base substrate, of the seventh edge and the orthographic projection, on the base substrate, of the eleventh edge is greater than a distance in the second direction between the orthographic projection, on the base substrate, of the ninth edge and the orthographic projection, on the base substrate, of the eleventh edge.

13. The display panel according to claim 11, wherein the orthographic projection, on the base substrate, of the seventh edge is located on the orthographic projection, on the base substrate, of the first gate line.

14. The display panel according to claim 10, wherein the display panel further comprises a light emitting unit, the pixel driving circuit further comprises a fifth transistor, a sixth transistor and a seventh transistor, the fifth transistor comprises a first electrode connected to the power line and a second electrode connected to the first electrode of the driving transistor, the sixth transistor comprises a first electrode connected to the second electrode of the driving transistor and a second electrode connected to a first electrode of the light emitting unit, and the seventh transistor comprises a first electrode connected to a second initial signal line and a second electrode connected to the first electrode of the light emitting unit,
the display panel further comprises:
a first active layer provided between the base substrate and the first conductive layer, the first active layer comprising a first active part, a fifth active part, a sixth active part and a seventh active part, the first active part being configured to form a channel region of the first transistor, the fifth active part being configured to form a channel region of the fifth transistor, the sixth active part being configured to form a channel region of the sixth transistor, and the seventh active part being configured to a channel region of the seventh transistor,
the first conductive layer further comprises:
an enabling signal line, an orthographic projection, on the base substrate, of the enabling signal line extending in the first direction and covering an orthographic projection, on the base substrate, of the fifth active part and an orthographic projection, on the base substrate, of the sixth active part, a portion of the enabling signal line being configured to form a gate electrode of the fifth transistor, and another portion of the enabling signal line being configured to form a gate electrode of the sixth transistor; and
a first reset signal line, an orthographic projection, on the base substrate, of the first reset signal line extending in the first direction and covering an orthographic projection, on the base substrate, of the first active part, and a portion of the first reset signal line being configured to form the gate electrode of the first transistor; and
a second reset signal line, an orthographic projection, on the base substrate, of the second reset signal line extending in the first direction and covering an orthographic projection, on the base substrate, of the seventh active part, and a portion of the second reset signal line being configured to form a gate electrode of the seventh transistor,
wherein the orthographic projection, on the base substrate, of the enable signal line is located at a side, away from the orthographic projection of the first gate line on the base substrate, of the orthographic projection, on the base substrate, of the first conductive part,
the orthographic projection, on the base substrate, of the second reset signal line is located at a side, away from the orthographic projection of the first conductive part on the base substrate, of the orthographic projection, on the base substrate, of the enable signal line, and
the orthographic projection, on the base substrate, of the first reset signal line is located at a side, away from the orthographic projection of the first conductive part on the base substrate, of the orthographic projection, on the base substrate, of the first gate line.

15. The display panel according to claim 14, wherein the first direction is a row direction, and the second reset signal line in the pixel driving circuit in a previous row adjacent to a current row is multiplexed as the first reset signal line in the pixel driving circuit in the current row.

16. The display panel according to claim 14, wherein the first direction is a row direction, and the third conductive layer further comprises the first initial signal line,
an orthographic projection, on the base substrate, of the first initial signal line extends in the first direction and is located at a side, away from the orthographic projection of the first conductive part on the base substrate, of an orthographic projection, on the base substrate, of the first reset signal line,
the orthographic projection, on the base substrate, of the first initial signal line in the pixel driving circuit in a next row adjacent to a current row is located between the orthographic projection, on the base substrate, of the second reset signal line in the pixel driving circuit in the current row and the orthographic projection, on the base substrate, of the first conductive part in the pixel driving circuit in the current row, and the orthographic projection, on the base substrate, of the first initial signal line in the pixel driving circuit in the next row is at least partially overlapped with the orthographic projection, on the base substrate, of the enable signal line in the pixel driving circuit in the current row.

17. The display panel according to claim 14, wherein the first direction is a row direction, and the fourth conductive layer further comprises the second initial signal line,
an orthographic projection, on the base substrate, of the second initial signal line extends in the first direction and is located at a side, away from the orthographic projection of the first conductive part on the base substrate, of the orthographic projection, on the base substrate, of the second reset signal line,
the orthographic projection, on the base substrate, of the second initial signal line in the pixel driving circuit in a previous row adjacent to a current row is located between the orthographic projection, on the base substrate, of the first reset signal line in the pixel driving circuit in the current row and the orthographic projection, on the base substrate, of the first gate line in the pixel driving circuit in the current row.

18. The display panel according to claim 2, wherein the display panel further comprises:
a second active layer provided between the first conductive layer and the fourth conductive layer and comprising an eighth active part, the eighth active part being configured to form a channel region of the eighth transistor; and
a fifth conductive layer provided on a side, away from the base substrate, of the fourth conductive layer and comprising a power line, the power line comprising a first extension part, a second extension part and a third extension part, and the second extension part being connected between the first extension part and the third extension part,
wherein a dimension in the first direction of an orthographic projection, on the base substrate, of the second extension part is greater than a dimension in the first direction of an orthographic projection, on the base substrate, of the first extension part and a dimension in the first direction of an orthographic projection, on the base substrate, of the third extension part, and
the orthographic projection, on the base substrate, of the second extension part covers the orthographic projection, on the base substrate, of the eighth active part, and an orthographic projection, on the base substrate, of the first bridging part.

19. The display panel according to claim 1, wherein the pixel driving circuit further comprises a capacitor, the capacitor comprises a first electrode connected to the gate electrode of the driving transistor and a second electrode connected to a power line,
the power line comprises a first extension part, a second extension part and a third extension part, and the second extension part is connected between the first extension part and the third extension part,
the first direction is a row direction, the display panel comprises a plurality of repeating units arranged in the row direction and a column direction, each of the repeating units comprises two pixel driving circuits, the two pixel driving circuits comprise a first pixel driving circuit and a second pixel driving circuit arranged in the row direction, and the first pixel driving circuit and the second pixel driving circuit are arranged in a mirrored and symmetrical manner,
the pixel driving circuits in each column are provided to correspond to one power line, and in a same repeating unit, the second extension parts of two power lines are connected,
the display panel further comprises a second conductive layer, the second conductive layer is provided between the first conductive layer and the fourth conductive layer, and the second conductive layer comprises:
a fourth conductive part, an orthographic projection, on the base substrate, of the fourth conductive part being at least partially overlapped with an orthographic projection, on the base substrate, of the first conductive part, and the fourth conductive part being configured to form the second electrode of the capacitor,
in the repeating units adjacent in the row direction, adjacent fourth conductive parts are connected.

20. The display panel according to claim 19, wherein the second conductive layer further comprises a first connection part, and in the repeating units adjacent in the row direction, the adjacent fourth conductive parts are connected by the first connection part,
the pixel driving circuit further comprises a fifth transistor, and the fifth transistor comprises a first electrode connected to the power line and a second electrode connected to the first electrode of the driving transistor,
the display panel further comprises a first active layer provided between the base substrate and the first conductive layer, and the first active layer comprises:
a third active part configured to form a channel region of the driving transistor;
a fifth active part configured to form a channel region of the fifth transistor; and
a ninth active part connected to a side, away from the third active part, of the fifth active part, and connected between two fifth active parts in the repeating units adjacent in the row direction, and
the fourth conductive layer further comprises:
a second bridging part respectively connected to the ninth active part and the first connection part through via-holes, and connected to the power line through a via-hole.

21-22. (canceled)
